(19) United States
(12) Patent Application Publication
(10) Pub. No.: US 2007/0128815 A1
(43) Pub. Date: Jun. 7, 2007

(54) NONVOLATILE SEMICONDUCTOR MEMORY AND FABRICATION METHOD FOR THE SAME

(75) Inventors: Naohisa Iino, Yokohama-shi (JP); Fumitaka Arai, Yokohama-shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 11/563,073

(22) Filed: Nov. 24, 2006

(30) Foreign Application Priority Data
Dec. 1, 2005 (JP) 2005-348371

(51) Int. Cl. H01L 21/336; H01L 29/76

(52) U.S. Cl. 438/297; 257/314

(57) ABSTRACT

A nonvolatile semiconductor memory includes a plurality of active regions AA extending along the column direction isolated from each other by element isolating regions; a plurality of word lines/control gate lines extending along the row direction perpendicular to the plurality of active regions; and memory cell transistors each having a SOI semiconductor layer, source/drain regions, a tunneling insulating film provided on the SOI semiconductor layer, a floating gate metallic/polysilicon electrode layer sandwiched between the source/drain regions disposed on the tunneling insulating film on the semiconductor layer, an inter-gate insulating film disposed on the floating gate metallic/polysilicon electrode layer, and a control gate metallic electrode layer disposed on the floating gate metallic/polysilicon electrode layer via the inter-gate insulating film.

### CROSS REFERENCE TO RELATED APPLICATIONS AND INCORPORATION BY REFERENCE

This application is based upon and claims the benefit of priority from prior Japanese Patent Application P2005-348371 filed on Dec. 1, 2005; the entire contents of which are incorporated by reference herein.

### BACKGROUND OF THE INVENTION

1. FIELD OF THE INVENTION

The present invention relates to a nonvolatile semiconductor memory using silicon-on-insulator (SOI) substrate. In particular, it relates to the nonvolatile semiconductor memory and fabrication method for the same characterized by a higher-speed performance and a fabrication process miniaturization of fine patterns.

2. DESCRIPTION OF THE RELATED ART

A NAND flash EEPROM is known as an electrically erasable/programmable and highly integrated nonvolatile semiconductor memory. Each of memory cell transistors in the NAND flash EEPROM has a ‘stacked gate structure’ constructed by stacking a floating gate electrode layer for charge accumulation via an insulating film on a semiconductor substrate, and a control gate electrode layer disposed on the floating gate electrode layer via an inter-gate insulating film.

A NAND cell unit is constructed by serially connecting a plurality of memory cell transistors along the column direction with a source or drain region shared by adjacent memory cell transistors, and further disposing a select gate transistor at either end of the serially connected memory cell transistors.

A memory cell array has a plurality of NAND memory cell units aligned in a matrix. Furthermore, the plurality of NAND cell units aligned in parallel to the row direction is called a NAND cell block. The gate electrodes of a plurality of select gate transistors aligned in the same row direction are connected to the same select gate line, and the control gate electrodes of a plurality of memory cell transistors aligned in the same row direction are connected to the same control gate line.

As the process miniaturization of fine patterns of memory cell transistors develops, influences of capacitive-coupling effects between adjacent memory cell transistors, short-channel effects in the conductive channel of the memory cell transistors and the select gate transistors, influences of the parasitic capacitance in the STI region, and influences of the parasitic capacitance between each channel regions of the memory cell transistors and the semiconductor substrate are very much increasing. Therefore, the influences of the capacitive-coupling, the parasitic capacitances and short-channel effects should be much reduced. Furthermore, as memory cell transistors are miniaturized, the aspect ratio of gate contact holes for gate processing increases, resulting in increase in difficulty of the fabrication processing.

The stacked gate structure is formed through collective processing after formation of a two-layer gate structure made up of a floating gate and a control gate.

A NAND EEPROM having active areas for forming element regions, isolated from each other through shallow trench isolations (STIs), formed in a lattice structure in a SOI layer on a SOI substrate, and memory cells established in the active areas has already been disclosed (for example, see Japanese Patent Application Laid-open No. Hei 11-163303).

Meanwhile, a fabrication method of an insulating gate transistor by depositing an insulating film on the SOI layer surface via a silicon oxide film, forming an opening in a gate electrode formation region of the insulating film, implanting ions therein, forming a source and a drain through annealing process, and then embedding a metal gate, has also already been disclosed (for example, see Japanese Patent Application Laid-open No. 2001-185731).

### SUMMARY OF THE INVENTION

An aspect of the present invention inheres in a nonvolatile semiconductor memory which includes: a semiconductor layer disposed on an insulating layer; a plurality of active regions extending along the column direction disposed in the semiconductor layer and isolated from each other by element isolating regions; a plurality of word lines extending along the row direction perpendicular to the plurality of active regions; and a plurality of memory cell transistors arranged in a matrix on the semiconductor layer. Each of the memory cell transistors includes source/drain regions provided on the plurality of active regions; a floating gate polysilicon electrode layer sandwiched between the source/drain regions via a tunneling insulating film provided on the semiconductor layer; an inter-gate insulating film disposed on the floating gate polysilicon electrode layer; and a control gate metallic electrode layer disposed on the floating gate polysilicon electrode layer via the inter-gate insulating film.

Another aspect of the present invention inheres in a nonvolatile semiconductor memory which includes a semiconductor layer disposed on an insulating layer; a plurality of active regions extending along the column direction disposed in the semiconductor layer and isolated from each other by element isolating regions; a plurality of control gate lines extending along the row direction perpendicular to the plurality of active regions; and a plurality of memory cell transistors arranged in a matrix on the semiconductor layer. Each of the memory cell transistors includes source/drain regions provided on the plurality of active regions; a floating gate electrode layer sandwiched between the source/drain regions and disposed via a tunneling insulating film provided on the semiconductor layer; an inter-gate insulating film disposed on sidewalls of the floating gate electrode layer and on the tunneling insulating film on the source/drain regions; and a control gate metallic electrode layer disposed facing the source/drain regions via the tunneling insulating film and the inter-gate insulating film and touching the sidewalls of the floating gate electrode layer via the inter-gate insulating film.

Another aspect of the present invention inheres in a fabrication method for a nonvolatile semiconductor memory, which includes forming a tunneling insulating film on a semiconductor layer, which is formed on an insulating layer; forming a floating gate polysilicon electrode layer on the tunneling insulating film; etching and removing the floating gate polysilicon electrode layer, the tunneling insulating film, the semiconductor layer, and the insulating layer; forming an element isolating region; depositing an inter-gate insulating film on the floating gate polysilicon electrode layer and the element isolating region, and a nitride film on the inter-gate insulating film consecutively; etching and removing the nitride film, the inter-gate insulating film, and the floating gate polysilicon electrode layer, exposing the tunneling insulating film; forming source/drain regions in the semiconductor layer; depositing an interlayer insulating film across the entire device surface; planarizing the entire device surface, and exposing the nitride film and the interlayer insulating film; removing the nitride film; depositing a control gate metallic electrode layer across the entire device surface; planarizing the entire device surface until the interlayer insulating film is exposed, and filling in and forming the control gate metallic electrode layers through a metal damascene process.

### BRIEF DESCRIPTION OF THE DRAWINGS

FIG. 1 shows a cross-section of a memory cell in a nonvolatile semiconductor memory according to a first embodiment of the present invention;

FIG. 2 is a schematic circuit diagram of a NAND flash memory as the nonvolatile semiconductor memory according to the first embodiment of the present invention;

FIG. 3 schematically shows a plan view pattern of the nonvolatile semiconductor memory according to the first embodiment of the present invention;

FIG. 4 schematically shows a cross-section of the nonvolatile semiconductor memory according to the first embodiment of the present invention, cut along the line I-I of FIG. 3 describing a step of a fabrication process thereof;

FIG. 5 schematically shows a cross-section of the nonvolatile semiconductor memory according to the first embodiment of the present invention, cut along the line I-I of FIG. 3 describing a step of a fabrication process thereof;

FIG. 6 schematically shows a cross-section of the nonvolatile semiconductor memory according to the first embodiment of the present invention, cut along the line I-I of FIG. 3 describing a step of a fabrication process thereof;

FIG. 7 schematically shows a cross-section of the nonvolatile semiconductor memory according to the first embodiment of the present invention, cut along the line I-I of FIG. 3 describing a step of a fabrication process thereof;

FIG. 8 schematically shows a cross-section of the nonvolatile semiconductor memory according to the first embodiment of the present invention, cut along the line I-I of FIG. 3 describing a step of a fabrication process thereof;

FIG. 9 schematically shows a cross-section of the nonvolatile semiconductor memory according to the first embodiment of the present invention, cut along the line I-I of FIG. 3 describing a step of a fabrication process thereof;

FIG. 10 schematically shows a cross-section of the nonvolatile semiconductor memory according to the first embodiment of the present invention, cut along the line II-II of FIG. 3 describing a step of a fabrication process thereof;

FIG. 11 schematically shows a cross-section of a memory cell with a sidewall control gate structure in a nonvolatile semiconductor memory according to a second embodiment of the present invention;

FIG. 12 schematically shows a plan view pattern of a nonvolatile semiconductor memory according to the second embodiment of the present invention;

FIG. 13 is a schematic circuit diagram of a NAND flash memory, having the memory cell with the sidewall control gate structure as the nonvolatile semiconductor memory, according to the second embodiment of the present invention;

FIG. 14 schematically shows a cross-section of the nonvolatile semiconductor memory, according to the second embodiment of the present invention, cut along the line I-I of FIG. 12 describing a step in the fabrication process thereof;

FIG. 15 schematically shows a cross-section of the nonvolatile semiconductor memory, according to the second embodiment of the present invention, cut along the line II-II of FIG. 12 describing a step in the fabrication process thereof;

FIG. 16 schematically shows a cross-section of the nonvolatile semiconductor memory, according to the second embodiment of the present invention, cut along the line III-III of FIG. 12 describing a step in the fabrication process thereof;

FIG. 17 schematically shows a cross-section of the nonvolatile semiconductor memory, according to the second embodiment of the present invention, cut along the line III-III of FIG. 12 describing a step in the fabrication process thereof;

FIG. 18 schematically shows a cross-section of the nonvolatile semiconductor memory, according to the second embodiment of the present invention, cut along the line I-I of FIG. 12 describing a step in the fabrication process thereof;

FIG. 19 schematically shows a cross-section of the nonvolatile semiconductor memory, according to the second embodiment of the present invention, cut along the line I-I of FIG. 12 describing a step in the fabrication process thereof;

FIG. 20 schematically shows a cross-section of the nonvolatile semiconductor memory, according to the second embodiment of the present invention, cut along the line II-II of FIG. 12 describing a step in the fabrication process thereof;

FIG. 21 schematically shows a cross-section of the nonvolatile semiconductor memory, according to the second embodiment of the present invention, cut along the line III-III of FIG. 12 describing a step in the fabrication process thereof;

FIG. 22 schematically shows a cross-section of the nonvolatile semiconductor memory, according to the second embodiment of the present invention, cut along the line III-III of FIG. 12 describing a step in the fabrication process thereof;

FIG. 23 shows a cross-section of a memory cell in a nonvolatile semiconductor memory according to a third embodiment of the present invention;

FIG. 24 schematically shows a cross-section of the nonvolatile semiconductor memory, according to the third embodiment of the present invention, cut along the line I-I of FIG. 12 describing a step in the fabrication process thereof;

FIG. 25 schematically shows a cross-section of the nonvolatile semiconductor memory, according to the third embodiment of the present invention, cut along the line I-I of FIG. 12 describing a step in the fabrication process thereof;

FIG. 26 schematically shows a cross-section of the nonvolatile semiconductor memory, according to the third embodiment of the present invention, cut along the line I-I of FIG. 12 describing a step in the fabrication process thereof;

FIG. 27 schematically shows a cross-section of the nonvolatile semiconductor memory, according to the third embodiment of the present invention, cut along the line I-I of FIG. 12 describing a step in the fabrication process thereof;

FIG. 28 schematically shows a cross-section of the nonvolatile semiconductor memory, according to the third embodiment of the present invention, cut along the line I-I of FIG. 12 describing a step in the fabrication process thereof;

FIG. 29 schematically shows a cross-section of the nonvolatile semiconductor memory, according to the third embodiment of the present invention, cut along the line II-II of FIG. 12 describing a step in the fabrication process thereof;

FIG. 30 schematically shows a cross-section of the nonvolatile semiconductor memory, according to the third embodiment of the present invention, cut along the line III-III of FIG. 12 describing a step in the fabrication process thereof;

FIG. 31 schematically shows a cross-section of the nonvolatile semiconductor memory, according to the third embodiment of the present invention, cut along the line III-III of FIG. 12 describing a step in the fabrication process thereof;

FIG. 32 is a schematic block diagram of a flash memory device and system as an application of the nonvolatile memory according to the first through the third embodiment of the present invention;

FIG. 33 is a block diagram schematically showing an internal structure of a memory card to which is applied the nonvolatile semiconductor memory according to the first through the third embodiment of the present invention;

FIG. 34 is a block diagram schematically showing an internal structure of a memory card to which is applied the nonvolatile semiconductor memory according to the first through the third embodiment of the present invention;

FIG. 35 is a block diagram schematically showing an internal structure of a memory card to which is applied the nonvolatile semiconductor memory according to the first through the third embodiment of the present invention;

FIG. 36 is a diagram schematically showing an IC card to which is applied the nonvolatile semiconductor memory according to the first through the third embodiment of the present invention;

FIG. 37 is a block diagram schematically showing an internal structure of the IC card to which is applied the nonvolatile semiconductor memory according to the first through the third embodiment of the present invention; and

FIG. 38 is a block diagram schematically showing an internal structure of the IC card to which is applied the nonvolatile semiconductor memory according to the first through the third embodiment of the present invention.

### DETAILED DESCRIPTION OF THE INVENTION

Various embodiments of the present invention will be described with reference to the accompanying drawings. It is to be noted that the same or similar reference numerals are applied to the same or similar parts and elements throughout the drawings, and the description of the same or similar parts and elements will be omitted or simplified.

Referring to the drawings, embodiments of the present invention are described below. The embodiments shown below exemplify an apparatus and a method that are used to implement the technical ideas according to the present invention, and do not limit the technical ideas according to the present invention to those that appear below. These technical ideas, according to the present invention, may receive a variety of modifications that fall within the claims.

Next, a first to a third embodiment of the present invention are described while referencing drawings. Note that those drawings are merely schematics and thus relationship between thickness of respective parts and two-dimensional size thereof and ratio of respective parts in thickness may be inconsistent with reality according to the present invention. Moreover, it is natural that there are parts differing in relationship and ratio of dimensions among the drawings.

The technical ideas according to the present invention may be modified into a variety of modifications within the scope of the claimed invention.

Nonvolatile semiconductor memory and a fabrication method for the same according to the present invention allows reduction in the aspect ratio, implementation of simpler processing and reduction in the value of the parasitic capacitance between adjacent cells, miniaturization, higher integration, and simpler processing of a memory cell array, and low power consumption and higher speed operability.

### FIRST EMBODIMENT

(Basic Structure)

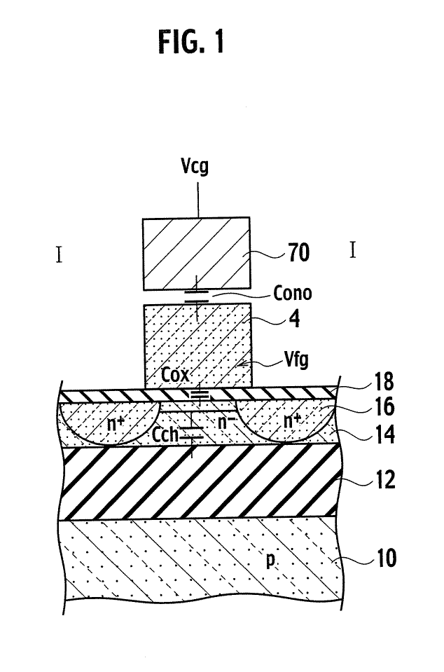

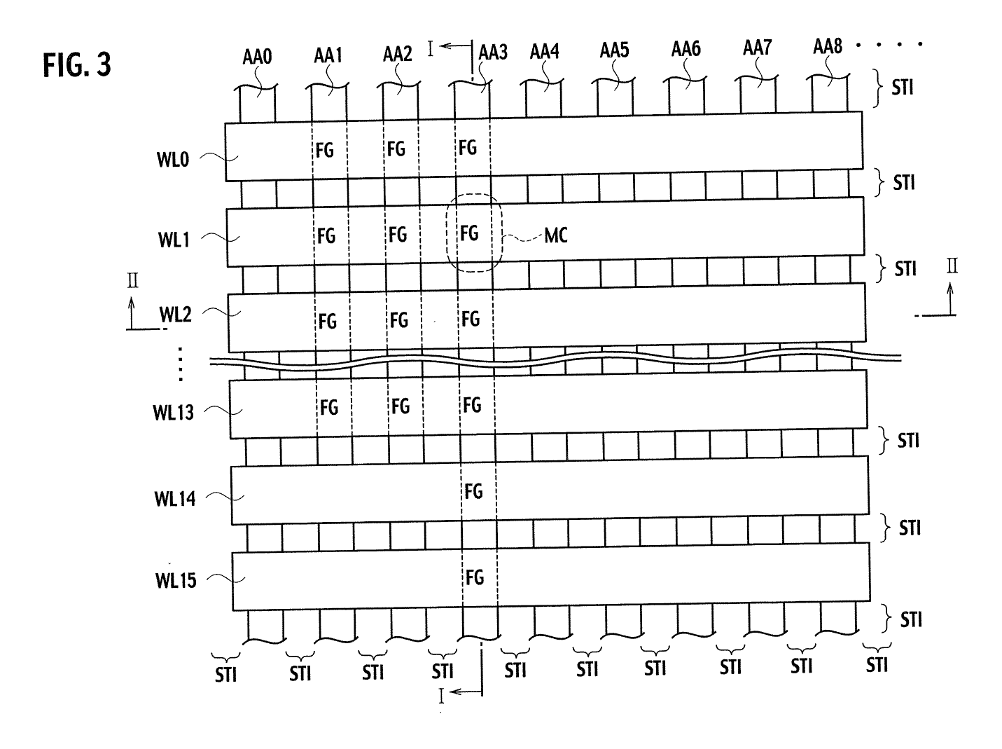

The basic structure of a memory cell transistor in a nonvolatile semiconductor memory according to the first embodiment of the present invention is, as shown in FIG. 1, a stacked structure including a SOI insulating layer 12 formed in a semiconductor substrate 10, a SOI semiconductor layer 14 formed on the SOI insulating layer 12, n⁺ source/drain regions 16 disposed facing each other in the SOI semiconductor layer 14, a tunneling insulating film 18 disposed on the SOI semiconductor layer 14, a floating gate polysilicon electrode layer 4 disposed on a channel region, which is sandwiched between the n⁺ source/drain regions 16, via the tunneling insulating film 18, and a control gate metallic electrode layer 70 disposed on the floating gate polysilicon electrode layer 4 via an inter-gate insulating film 25. FIG. 1 corresponds to a memory cell transistor structure in a cross-section of an active region in a plan view pattern structure shown in FIG. 3 cut along the line I-I in the column direction.

(NAND Circuit Structure)

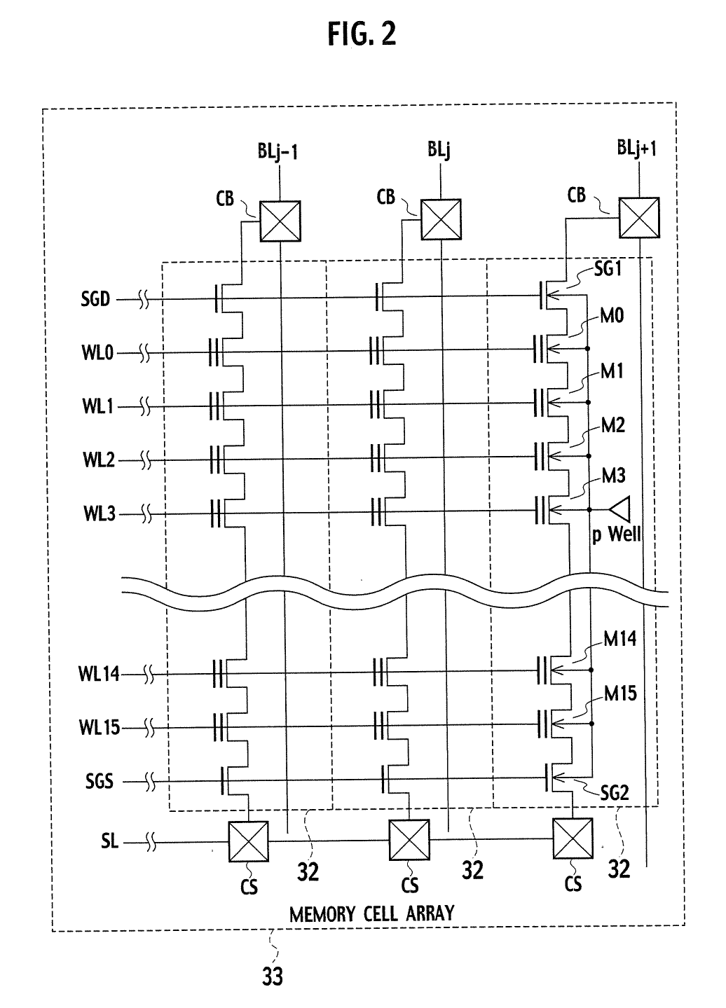

As schematically shown in FIG. 2, a circuit structure of a memory cell array 33 in the nonvolatile semiconductor memory according to the first embodiment of the present invention includes a circuit structure of a NAND memory cell array.

Each of a plurality of NAND cell units 32 is constituted by memory cell transistors MO through M15 and select gate transistors SG1 and SG2, as shown in detail in FIG. 2. The drains of the select gate transistors SG1 are connected to the bit lines . . . , BLⱼ₋₁, BLⱼ, BLⱼ₊₁, . . . via respective bit line contacts CB, while the sources of the select gate transistors SG2 are connected to the common source line SL via respective source line contacts CS.

A plurality of memory cell transistors M0 through M15 are serially connected extending along the column direction of a plurality of bit lines BLⱼ₋₁, BLⱼ, BLⱼ₊₁ via n⁺ source/drain regions of the respective memory cell transistors, the select gate transistors SG1 and SG2 are disposed on either end the memory cell transistors M0 through M15, and the bit line contacts CB and the source line contacts CS are connected via these select gate transistors SG1 and SG2. As a result, this constitutes each of NAND cell units 32, which are arranged in parallel extending along the row direction of the plurality of word lines WL0, WL1, WL2, WL3, . . . , WL14, and WL15 perpendicular to the plurality of bit lines . . . , BLⱼ₋₁, BLⱼ, BLⱼ₊₁, . . . .

Note that the memory cell transistors M0 through M15 may include channel regions with the same conductivity as the n⁺ source/drain regions 16, configuring a depletion mode MIS transistor. Similarly, the memory cell transistors M0 through M15 may include channel regions with the opposite conductivity to that of the n⁺ source/drain regions 16, configuring an enhancement mode MIS transistor. A ‘MIS transistor’ is defined as a field-effect transistor (FET) or a static induction transistor (SIT) configured to control a conduction of the channel current by an application of a gate voltage via an insulating film (gate insulating film) disposed between a gate electrode and a channel region. It is called a metal-oxide semiconductor field-effect transistor (MOSFET) when a silicon oxide film (SiO₂) is used as the gate insulating film.

(Plan View Pattern Structure)

FIG. 3 schematically shows a plan view pattern of a memory cell array in the nonvolatile semiconductor memory according to the first embodiment of the present invention.

As shown in FIG. 1, the nonvolatile semiconductor memory according to the first embodiment of the present invention has a plurality of memory cell transistors disposed in a matrix on a SOI insulating layer, including a plurality of active regions AA1, AA2, AA3, AA4, . . . , AA8 extending along the column direction and isolated from each other by element isolating regions STIs, and a plurality of word lines WL0, WL1, WL2, . . . , WL15 extending along the row direction orthogonal to the plurality of active regions AA1, AA2, AA3, AA4, . . . , AA8; and it further includes memory cell transistors MC, each including a floating gate FG, disposed on the intersections of the plurality of active regions AA1, AA2, AA3, AA4, . . . , AA8 and the plurality of word lines WL0, WL1, WL2, . . . , WL15.

(Device Structure)

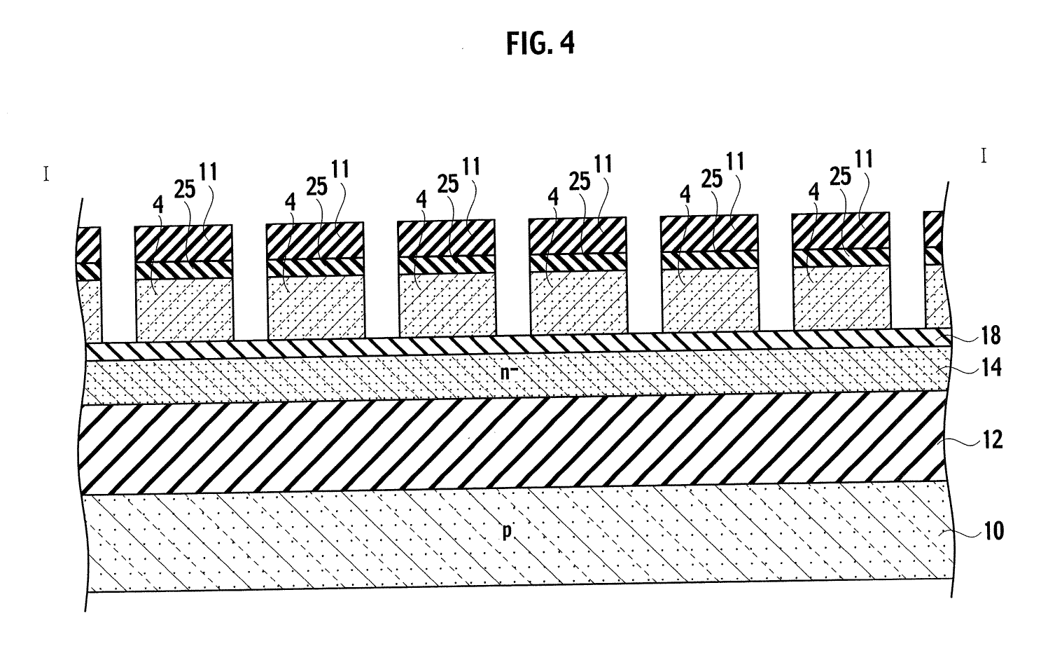

FIGS. 4 through 7 and 9 schematically show cross-sections of the nonvolatile semiconductor memory, according to the first embodiment of the present invention, cut along the line I-I of FIG. 3 describing steps in a fabrication process thereof.

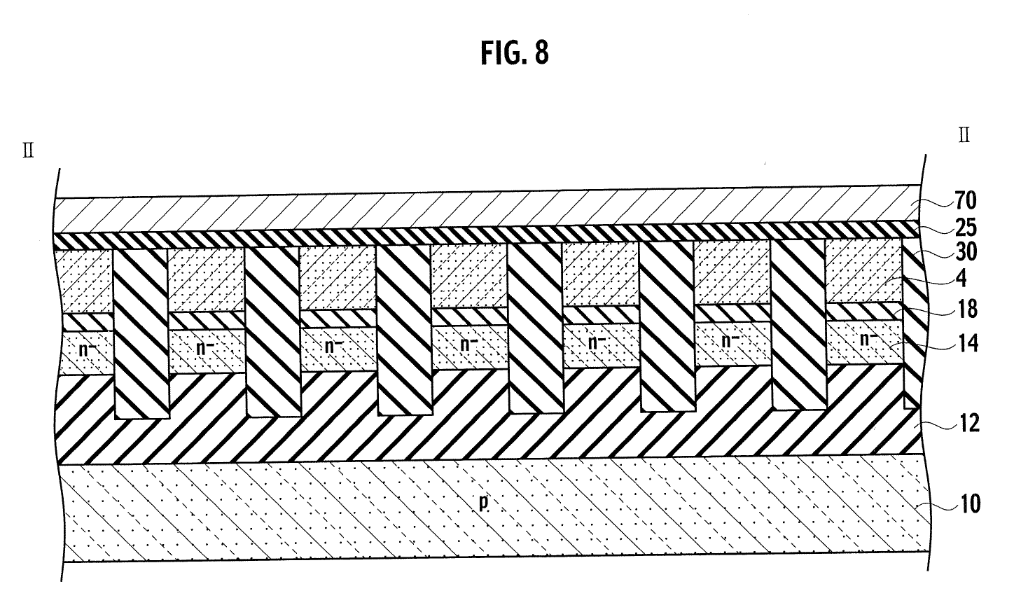

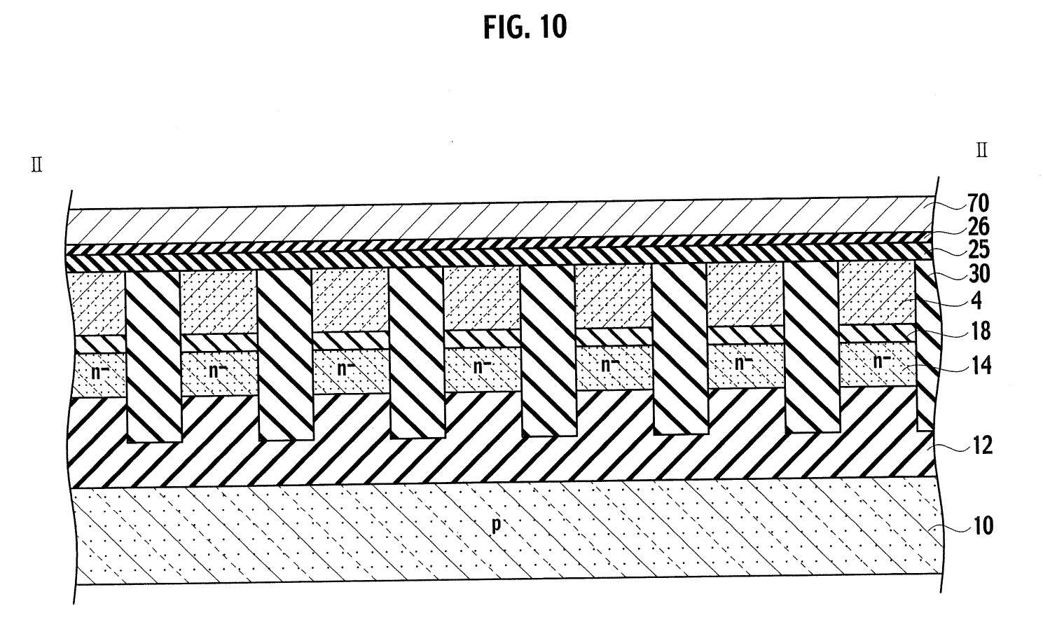

FIGS. 8 and 10 schematically show cross-sections of the nonvolatile semiconductor memory, according to the first embodiment of the present invention, cut along the line II-II of FIG. 3 describing steps in the fabrication process thereof. In FIG. 3, line I-I denotes a section line extending along the column direction on the active region AA3, and line II-II denotes a section line extending along the row direction on the word line WL2.

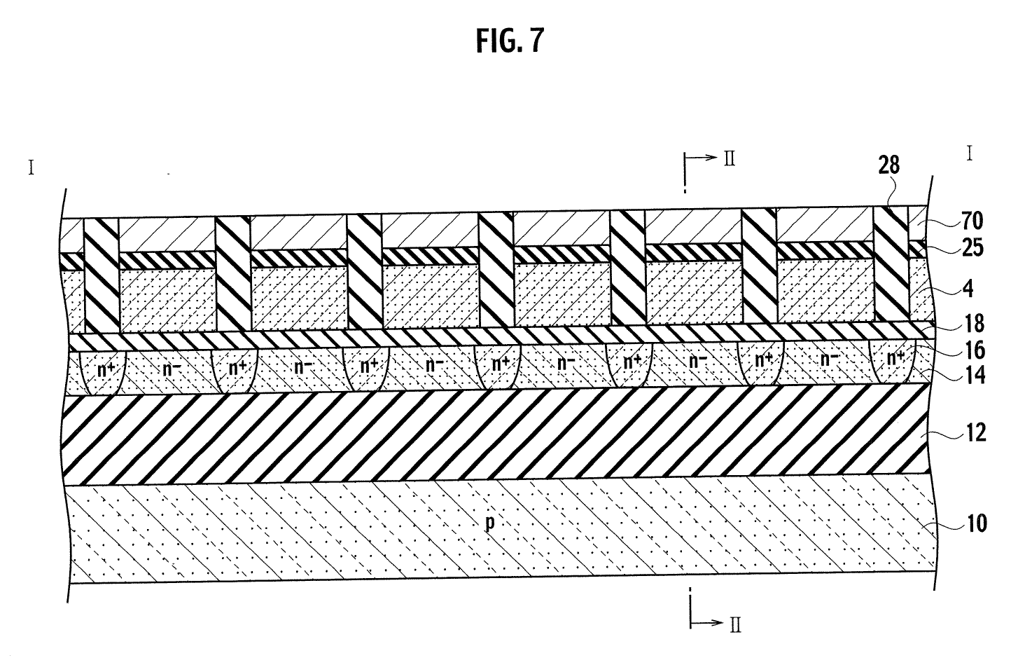

The stacked gate memory cell transistors in the nonvolatile semiconductor memory according to the first embodiment of the present invention are disposed on the intersections of the plurality of active regions AA1, AA2, AA3, AA4, . . . , AA8, . . . , which extend along the column direction and are isolated from each other by element isolating regions STI, and the plurality of word lines WL0, WL1, WL2, . . . , WL15, which extend along the row direction perpendicular to the plurality of active regions AA1, AA2, AA3, AA4, . . . , AA8, . . . ; and each of the memory cell transistors is constructed by a semiconductor substrate 10; a SOI insulating layer 12 disposed in the semiconductor substrate 10; a SOI semiconductor layer 14 disposed on the SOI insulating layer 12; n⁺ source/drain regions 16 disposed facing each other in the SOI semiconductor layer; a tunneling insulating film 18 disposed on the SOI semiconductor layer 14; a floating gate polysilicon electrode layer 4 disposed on the tunneling insulating film 18; an inter-gate insulating film 25 disposed on the floating gate polysilicon electrode layer 4; and a control gate metallic electrode layer 70 disposed on the inter-gate insulating film 25, as shown in FIGS. 7 and 8 or 9 and 10.

FIG. 7 schematically shows a cross-section cut along the line I-I on the active region AA3 of FIG. 3, and thereby showing that the memory cell transistors with the stacked gate structure shown in FIG. 1 are aligned extending along the column direction, constituting a NAND column. The stacked gate structures, each made up of the floating gate polysilicon electrode layer 4, the inter-gate insulating films 25 and the control gate metallic electrode layer 70 of each of the memory cell transistors, are isolated from each other by interlayer insulating films 28. In FIG. 7, the control gate metallic electrode layer 70 running perpendicular to the page of FIG. 7 correspond to the plurality of word lines WL0, WL1, WL2, . . . , WL15 shown in FIGS. 2 and 3.

FIG. 8 schematically shows a cross-section cut along the line II-II on the word line WL2 of FIG. 3, and thus corresponds to the cross-section cut along the line II-II shown in FIG. 7. As is apparent from FIG. 8, the stacked structures, each made up of the SOI semiconductor layer 14, the tunneling insulating film 18, and the floating gate polysilicon electrode layer 4 of each of the memory cell transistors, are isolated from each other by element isolating regions (STI) 30. In the structure shown in FIG. 8, the bottoms of respective STIs 30 are formed penetrating into the SOI insulating layer 12. The depth of the STIs 30 can be adjusted so that the bottoms of respective STIs 30 touch the surface of the SOI insulating layer 12 by adjusting the etching depth at the time of STI formation. Alternatively, the STIs 30 may be formed deep enough to reach the semiconductor substrate 10 through the SOI insulating layer 12. Namely, adjacent memory cell transistors formed on the plurality of active regions AA1, AA2, AA3, AA4, . . . , AA8, . . . extending along the column direction can be reliably isolated from each other along the row direction.

Furthermore, as is apparent from FIG. 8, the plurality of word lines WL0, WL1, WL2, . . . , WL15 is formed after forming the inter-gate insulating film (ONO film) 25 and the control gate metallic electrode layer 70 across the entire planarized device surface made up of the floating gate polysilicon electrode layers 4 and the STIs 30.

### Modified Example of the First Embodiments

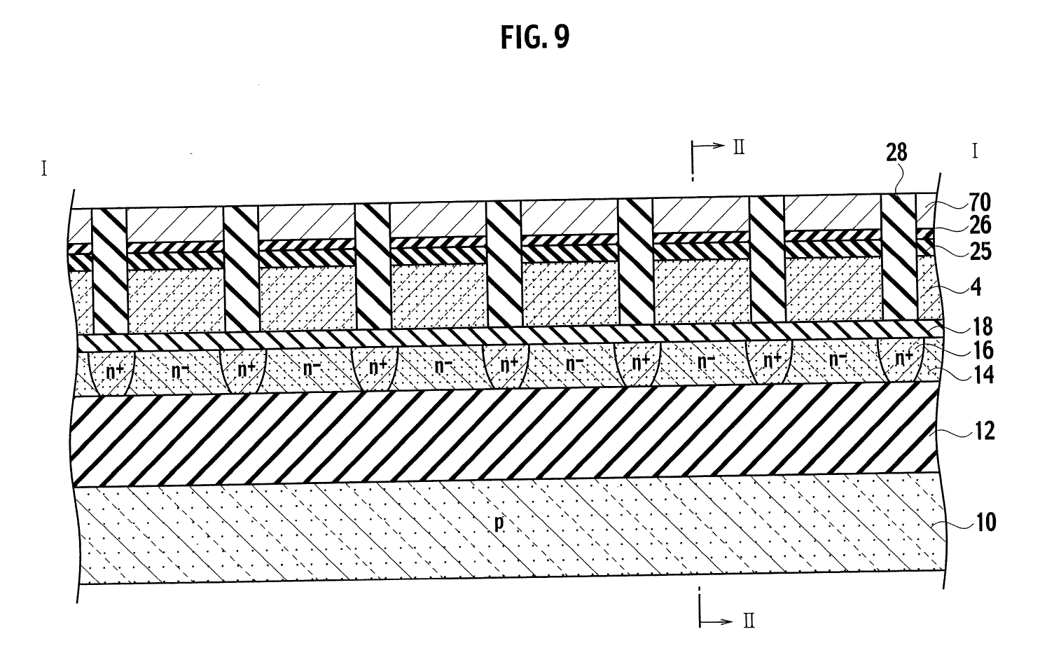

Memory cell transistors in nonvolatile semiconductor memory according to a modified example of the first embodiment of the present invention are disposed on the intersections of the plurality of active regions AA1, AA2, AA3, AA4, . . . , AA8, . . . , which extend along the column direction and are isolated from each other by STIs, and the plurality of word lines WL0, WL1, WL2,. . . , WL15, which extend along the row direction perpendicular to the plurality of active regions AA1, AA2, AA3, AA4, . . . , AA8, . . . ; and each of the memory cell transistors is constituted by the semiconductor substrate 10; the SOI insulating layer 12 disposed in the semiconductor substrate 10; the SOI semiconductor layer 14 disposed on the SOI insulating layer 12; the n⁺ source/drain regions disposed facing each other in the SOI semiconductor layer 14; the tunneling insulating film 18 disposed on the SOI semiconductor layer 14; the floating gate polysilicon electrode layer 4 disposed on the tunneling insulating film 18; the inter-gate insulating film 25 disposed on the floating gate polysilicon electrode layer 4; a buffer layer 26 disposed on the inter-gate insulating film 25; and the control gate metallic electrode layer 70 disposed on the buffer layer 26, as shown in FIGS. 9 and 10. A characteristic of the modified example of the first embodiment of the present invention is that the buffer layer 26 lies between the control gate metallic electrode layer 70 and the inter-gate insulating film 25; wherein the buffer layer 26 allows improvement in the adhesive characteristics between the control gate metallic electrode layer 70 and the inter-gate insulating film 25, and improvements in the reliability of the MIS structure made up of the control gate metallic electrode layer 70, the inter-gate insulating film 25, and the floating gate polysilicon electrode layer 4.

FIG. 9 schematically shows a cross-section cut along the line I-I on the active region AA3 of FIG. 3, and thereby showing that the memory cell transistors with the stacked gate structure shown in FIG. 1 are aligned extending along the column direction, constituting a NAND column. The stacked gate structures, each made up of the floating gate polysilicon electrode layer 4, the inter-gate insulating film 25, the buffer layer 26, and the control gate metallic electrode layer 70 of each of the memory cell transistors, are isolated from each other by interlayer insulating films 28. In FIG. 9, the control gate metallic electrode layer 70 running perpendicular to the page correspond to the plurality of word lines WL0, WL1, WL2, . . . , WL15 shown in FIGS. 2 and 3.

FIG. 10 schematically shows a cross-section cut along the line II-II on the word line WL2 of FIG. 3, and thus corresponds to the cross-section cut along the line II-II shown in FIG. 9. As is apparent from FIG. 10, the stacked structures, each made up of the SOI semiconductor layer 14, the tunneling insulating film 18, and the floating gate polysilicon electrode layer 4 of each of the memory cell transistors, are isolated from each other by STIs 30. In the structures shown in FIG. 10, the bottoms of the STIs 30 are formed penetrating into the SOI insulating layer 12. The depth of the STIs 30 can be adjusted so that the bottoms of the STIs 30 touch the surface of the SOI insulating layer 12 by adjusting the etching depth at the time of STI formation. Alternatively, the STIs 30 can be formed deep enough to reach the semiconductor substrate 10 through the SOI insulating layer 12. Namely, adjacent memory cell transistors formed on the plurality of active regions AA1, AA2, AA3, AA4, . . . , AA8, . . . extending along the column direction can be reliably isolated from each other along the row direction.

Furthermore, as is apparent from FIG. 10, the plurality of word lines WL0, WL1, WL2, . . . , WL15 is formed after forming the inter-gate insulating film (ONO film) 25, the buffer layer 26, and the control gate metallic electrode layer 70 across the entire planarized device surface made up of the floating gate polysilicon electrode layers 4 and the STIs 30.

(Select Gate Transistor)

Select gate transistors SG1, SG2 formed adjacent to the memory cell transistors M0 through M15 in the nonvolatile semiconductor memory according to the first embodiment of the present invention are constituted by the semiconductor substrate 10; the SOI insulating layer 12 formed in the semiconductor substrate 10; the SOI semiconductor layer 14 formed on the SOI insulating layer 12; the n⁺ source/drain regions 16 disposed facing each other in the SOI semiconductor layer 14; the tunneling insulating film 18 disposed on the SOI semiconductor layer 14; the floating gate polysilicon electrode layer 4 disposed on the tunneling insulating film 18; the inter-gate insulating film 25 having an opening disposed on the floating gate polysilicon electrode layer 4; and the control gate metallic electrode layer 70 disposed on the inter-gate insulating film 25 having the opening. The select gate transistors formed as such correspond to transistors SG1, SG2 having gate electrodes connected to the select gate lines SGD and SGS, as shown in FIG. 2, respectively.

The select gate lines SGD and SGS becoming gate electrodes of the select gate transistors SG1, SG2 and arranged in parallel to the plurality of word lines WL0, WL1, WL2, . . . , WL15 may be formed in the same manner as the control gate metallic electrode layer 70.

(Fabrication Method)

(a) First, a SOI substrate made up of a semiconductor substrate 10, a SOI insulating layer 12 formed in the semiconductor substrate 10, and a SOI semiconductor layer 14 formed on the SOI insulating layer 12 is prepared, a tunneling insulating film 18 is formed on the SOI semiconductor layer 14, and a floating gate polysilicon electrode layer 4 is then formed on the tunneling insulating film 18.

Here, SiO₂, sapphire (Al₂O₃), or the like is available as the materials for the SOI insulating layer 12 that allows achievement of the SOI structure. Monocrystalline silicon, silicon germanium (SiGe), or the like is available as the materials for the SOI semiconductor layer 14 provided on the SOI insulating layer 12. Furthermore, the SIMOX (Separation by implanted oxygen) method, a bonding method, or the like is available as a method for providing the SOI semiconductor layer 14 on the SOI insulating layer 12. With the SIMOX method, implanting oxygen ions into the semiconductor substrate 10 and then applying an annealing processing, forms the SOI insulating layer 12 in the semiconductor substrate 10 and the SOI semiconductor layer 14 on the SOI insulating layer 12. On the other hand, with the bonding method, the SOI insulating layer 12 is formed in one of two wafers, bonded together through an annealing process, and then one of the wafers is planarized and polished into a thin film, forming the SOI semiconductor layer 14 on the SOI insulating layer 12.

Although a silicon oxide film (SiO₂) is the typical material for the tunneling insulating film 18, silicon nitride (Si₃N₄), tantalum oxide (Ta₂O₅), titanium oxide (TiO₂), alumina (Al₂O₃), zirconium oxide (ZrO₂), or the like is also available.

(b) Next, the floating gate polysilicon electrode layer 4 is patterned, the floating gate polysilicon electrode layer 4, the tunneling insulating film 18, the SOI semiconductor layer 14, and the SOI insulating layer 12 are etched and removed through reactive ion etching (RIE) or the like, and a tetraethoxysilane (TEOS) insulating film or the like is filled in and then planarized through chemical mechanical polishing (CMP), thereby forming STIs 30.

(c) Next, an inter-gate insulating film 25 is deposited on the floating gate polysilicon electrode layer 4 and the STIs 30, and a nitride film 11 is then deposited on the inter-gate insulating film 25.

As for the materials for the inter-gate insulating film 25, Si₃N₄, Ta₂O₅, TiO₂, Al₂O₃, ZrO₂, oxide-nitride-oxide (ONO), phosphorous silicate glass (PSG), boron phosphorous silicate glass (BPSG), silicon oxinitride (SiON), barium titanium oxide (BaTiO₃), acid silicon fluoride (SiOₓF_{y}), an organic resin such as a polyimide or the like is available.

(d) Next, as shown in FIG. 4, the nitride film 11 is patterned, and the nitride film 11, the inter-gate insulating film 25, and the floating gate polysilicon electrode layer 4 are etched and removed through the RIE techniques or the like, exposing the tunneling insulating film 18.

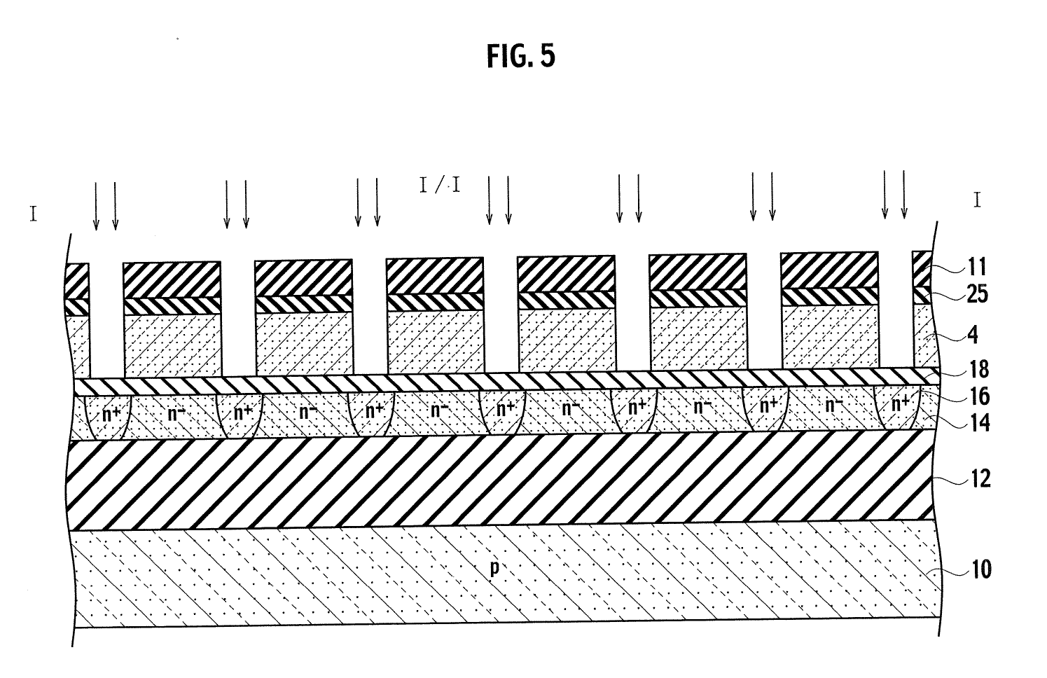

(e) Next, as shown in FIG. 5, with a predetermined accelerating energy and a predetermined amount of dosage, phosphorous (³¹P⁺) ions, arsenic (⁷⁵As⁺) ions, or the like are ion-implanted using ion implantation techniques and after an annealing process, n⁺ source/drain regions 16 are formed in the SOI semiconductor layer 14.

(f) An interlayer insulating film 28 is then deposited across the entire semiconductor device surface.

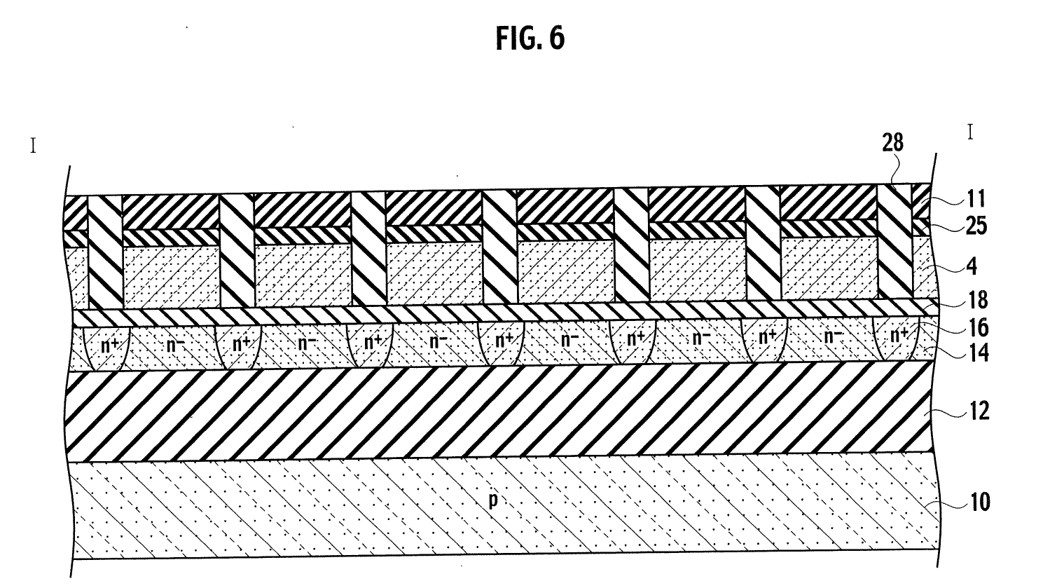

(g) Next, as shown in FIG. 6, the entire semiconductor device surface is planarized through the CMP techniques, exposing the nitride films 11 and the interlayer insulating film 28.

As a result, stacked structures, each made up of the floating gate polysilicon electrode layer 4 on the tunneling insulating film 18, the inter-gate insulating film 25 on the floating gate polysilicon electrode layer 4, and the nitride film 11 on the inter-gate insulating film 25, are isolated by the interlayer insulating films 28, as shown in FIG. 6.

(h) After the nitride films 11 are removed, a control gate metallic electrode layer 70 is deposited across the entire semiconductor device surface.

(i) Next, as shown in FIGS. 7 and 8, the entire semiconductor device surface is planarized through the CMP techniques until the interlayer insulating films 28 are exposed, and as a result, the control gate metallic electrode layer 70 is filled in and formed sandwiched by the interlayer insulating films 28 on both sides through a metal damascene process.

As a result, the control gate metallic electrode layer 70 extending along the row direction are filled in and formed in a stripe form along the row direction, resulting in formation of a plurality of word lines WL0 through WL15.

In other words, as shown in FIG. 8, the inter-gate insulating films (ONO films) 25 are already formed on the entire planarized device surface including the floating gate polysilicon electrode layers 4 and the STIs 30 in the process step (c), the control gate metallic electrode layer 70 is formed on the inter-gate insulating films (ONO films) 25 in the process step (h), and the control gate metallic electrode layer 70 is then isolated and formed through a metal damascene process in the process step (i), forming the plurality of word lines WL0, WL1, WL2, . . . , WL15.

The control gate metallic electrode layer 70 corresponds to word lines and thus may be constituted using a metallic silicide film. Silicide material such as Cobalt (Co), Nickel (Ni), Titanium (Ti), Tantalum (Ta), Platinum (Pt), Molybdenum (Mo), Tungsten (W), or Palladium (Pd), for example, may be applied as the material for the metallic silicide film.

The fabrication method for the nonvolatile semiconductor memory according to the modified example of the first embodiment of the present invention is basically the same as that of the first embodiment. As shown in FIGS. 9 and 10, a buffer layer 26 is provided between the inter-gate insulating film 25 and the control gate metallic electrode layer 70, which may be formed after formation of the inter-gate insulating film 25 in the process step (c). Subsequent process steps are the same as with the first embodiment.

Alternatively, in the process step (h), after the nitride films 11 are removed, the buffer layer 26 may be formed on the exposed inter-gate insulating films 25. Subsequent process steps are the same as with the first embodiment.

The fabrication method for the nonvolatile semiconductor memory having a stacked gate structure according to the first embodiment of the present invention, using which the floating gates are formed with polysilicon and which the control gates are formed with metallic electrode layers, has been described. Descriptions for the subsequent process steps are omitted, since a plurality of bit lines and peripheral circuit interconnect wirings are formed through a typical interconnect wirings/contacts formation processes.

According to the first embodiment of the nonvolatile semiconductor memory and the fabrication method for the same, using a metal damascene process in the formation of the control gate electrode layer allows reduction in the aspect ratio of the stacked structure, implementation of simpler processing and reduction in the value of parasitic capacitances between adjacent memory cells, miniaturization, higher integration, and simpler processing of a memory cell array, and low power consumption and higher speed operability of the nonvolatile semiconductor memory.

### Second Embodiments

(Basic Structure)

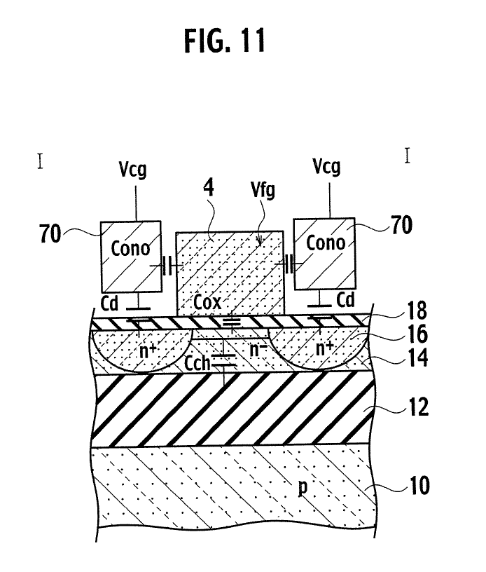

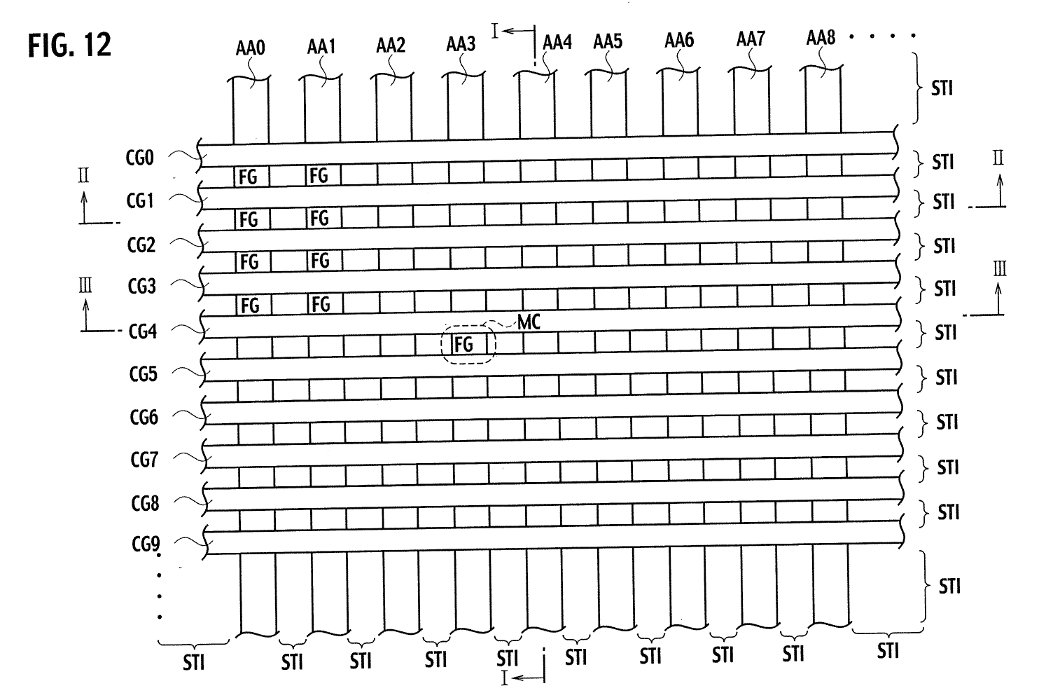

The basic structure of a memory cell transistor in a nonvolatile semiconductor memory according to the second embodiment of the present invention is, as shown in FIG. 11, a sidewall control gate structure including a SOI insulating layer 12 formed in a semiconductor substrate 10, a SOI semiconductor layer 14 formed on the SOI insulating layer 12, n⁺ source/drain regions 16 disposed facing each other in the SOI semiconductor layer 14, a tunneling insulating film 18 disposed on the SOI semiconductor layer 14, a floating gate polysilicon electrode layer 4 disposed on the SOI semiconductor layer 14, which is sandwiched between the n⁺ source/drain regions 16, via the tunneling insulating film 18, and the control gate metallic electrode layer 70 formed facing the n⁺ source/drain regions 16 via the tunneling insulating film 18 and formed facing the sidewalls of the floating gate polysilicon electrode layer 4 via inter-gate insulating films 25. FIG. 11 corresponds to a memory cell transistor structure in a cross-section of an active region AA4 cut along the line I-I in the column direction in a plan view pattern structure shown in FIG. 12.

According to the sidewall control gate structure, parasitic capacitances around the floating gate polysilicon electrode layer 4 can be reduced, and an amount of increase in the value of the capacitance between the control gate metallic electrode layer 70 and the floating gate polysilicon electrode layer 4 allows an amount of decrease in the value of write-in voltage V_{pgm}. As a result, a highly integrated nonvolatile semiconductor memory which is capable of operating at high speed, can be realized.

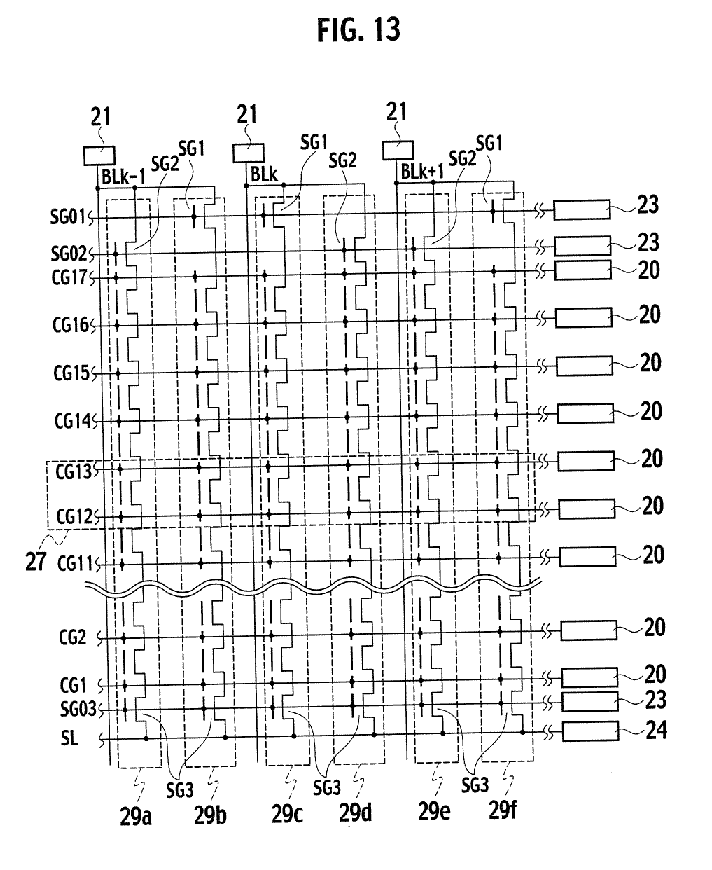

Meanwhile, the number of control gate lines must be two for one memory cell transistor of the sidewall control gate structure, while only one control gate line is necessary for one memory cell transistor of the stacked gate structure; thus the memory cell array with the stacked gate structure has a simpler circuit structure. However, actually, as is evident through comparison of FIG. 2 and FIG. 13, the number of control gate lines in the sidewall control gate structure is only one control gate line more than the number of control gate lines in the stacked gate structure. This is because a control gate line is shared with two adjacent memory cells, in other words, the two adjacent memory cells are controlled by a single control gate line.

(Plan View Pattern Structure)

FIG. 12 schematically shows a plan view pattern of a memory cell array having a sidewall control gate memory cell structure in the nonvolatile semiconductor memory according to the second embodiment of the present invention.

The nonvolatile semiconductor memory according to the second embodiment of the present invention has a plurality of memory cell transistors arranged in a matrix on a SOI insulating layer, as shown in FIGS. 11 and 12, including a plurality of active regions AA1, AA2, AA3, AA4, . . . , AA8, . . . extending along the column direction isolated from each other by STIs, and a plurality of control gate lines CG0, CG1, CG2 . . . , CG9 . . . extending along the row direction perpendicular to the plurality of active regions AA1, AA2, AA3, AA4, . . . , AA8 . . . . Moreover, the nonvolatile semiconductor memory according to the second embodiment of the present invention includes, as shown in FIG. 12, memory cell transistors MC, each having a floating gate FG, disposed sandwiched between adjacent control gate lines on the intersections of the plurality of active regions AA1, AA2, AA3, AA4, . . . , AA8, . . . and the plurality of control gate lines CG0, CG1, CG2, . . . , CG9, . . . .

(NAND Circuit Structure)

The matrix circuit structure of the nonvolatile semiconductor memory according to the second embodiment of the present invention is constituted by six NAND memory cell units 29a through 29f, a plurality of control gate lines CG1 through CG17, a plurality of select gate lines SG01 through SG03, a plurality of bit lines . . . , BLk−1, BLk, and BLk+1, . . . , a source line SL, a plurality of bit line driver circuits 21, a plurality of control gate line driver circuits 20, a plurality of select gate line driver circuits 23, and a source line driver circuit 24, as shown in FIG. 13, for example. In the example of FIG. 13, the NAND memory cell units 29a through 29f, each including sixteen serially connected memory cell transistors, one bit line side select gate transistor SG1 or SG2 disposed adjacent to the control gate line CG17, and one source line side select gate transistor SG3 disposed adjacent to the control gate line CG1. The sixteen serially connected memory cell transistors in the NAND memory cell units 29a through 29f are connected to the respective bit lines . . . , BLk−1, BLk, and BLk+1, . . . via the select gate transistor SG1 or SG2 and a source line SL via the select gate transistors SG3. Furthermore, in FIG. 13, a row of memory cells corresponding to one page in page mode may be defined by all the memory cell transistors 27 sandwiched between the two adjacent control gate lines CG12 and CG13, for example.

Note that as with the first embodiment, each of the memory cell transistors may be a depletion mode MIS transistor by including a channel region with the same conductivity as the n⁺ source/drain regions 16. Alternatively, each of the memory cell transistors may be an enhancement mode MIS transistor by including a channel region with the opposite conductivity to that of the n⁺ source/drain regions 16.

(Device Structure)

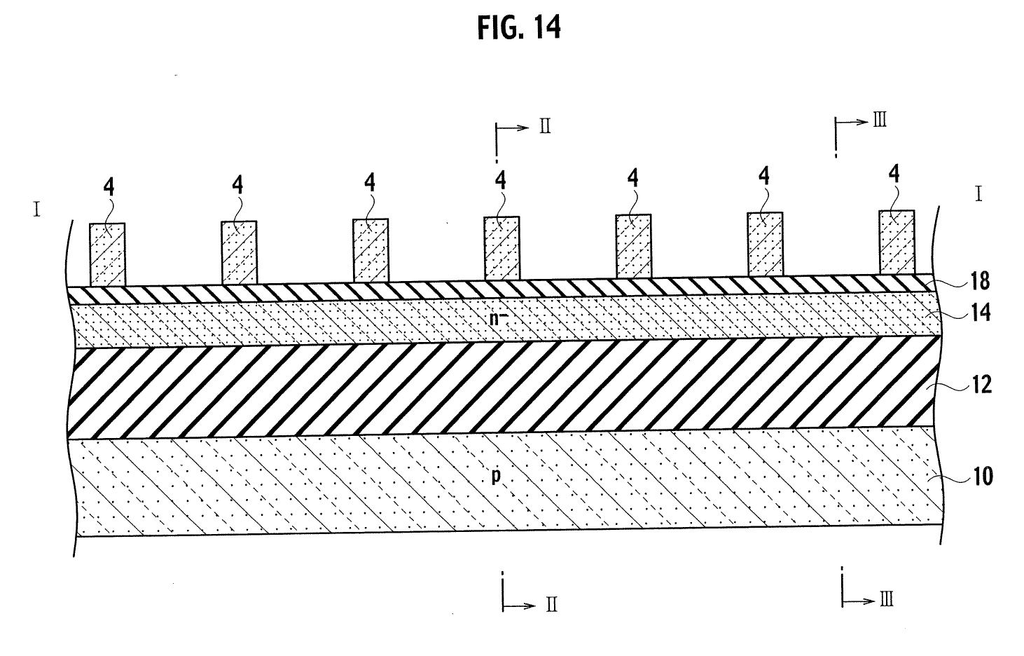

FIGS. 14, 18, and 19 schematically show cross-sections of the nonvolatile semiconductor memory, according to the second embodiment of the present invention, cut along the line I-I of FIG. 12 describing process steps in a fabrication method thereof.

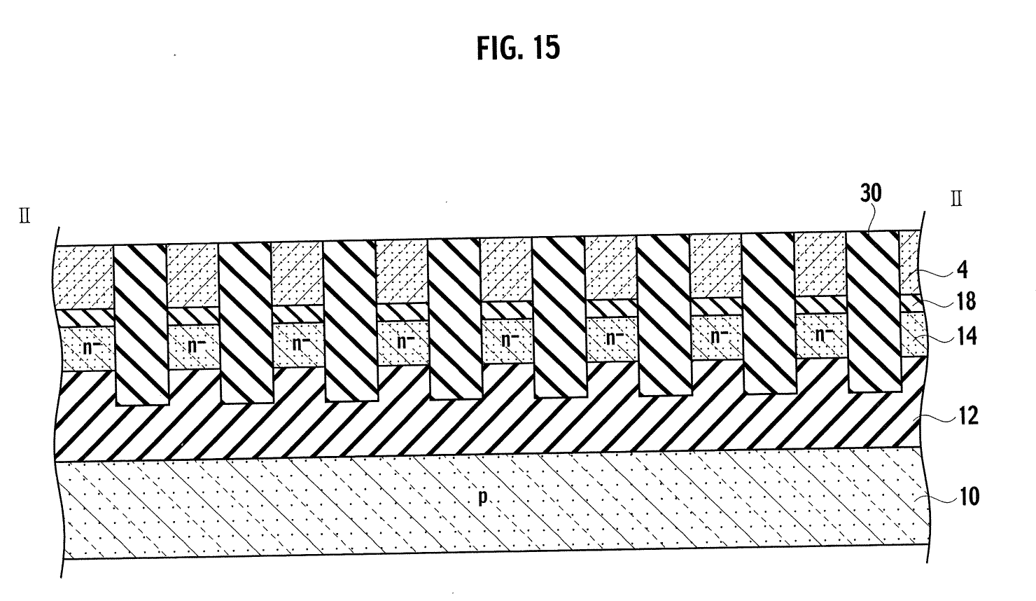

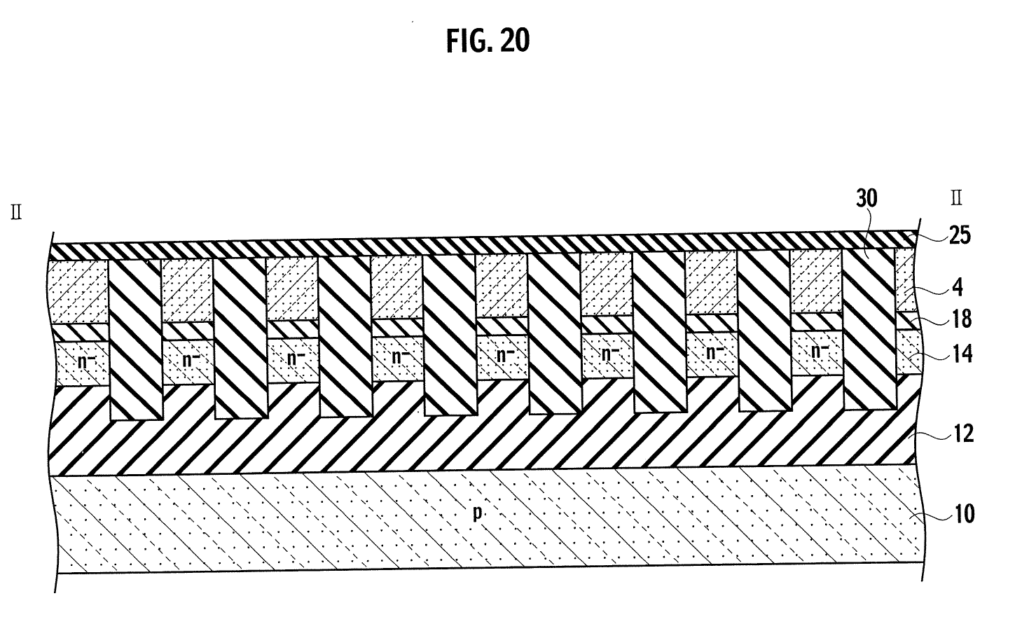

FIGS. 15 and 20 schematically show cross-sections of the nonvolatile semiconductor memory, according to the second embodiment of the present invention cut along the line II-II of FIG. 12 describing process steps in the fabrication method thereof.

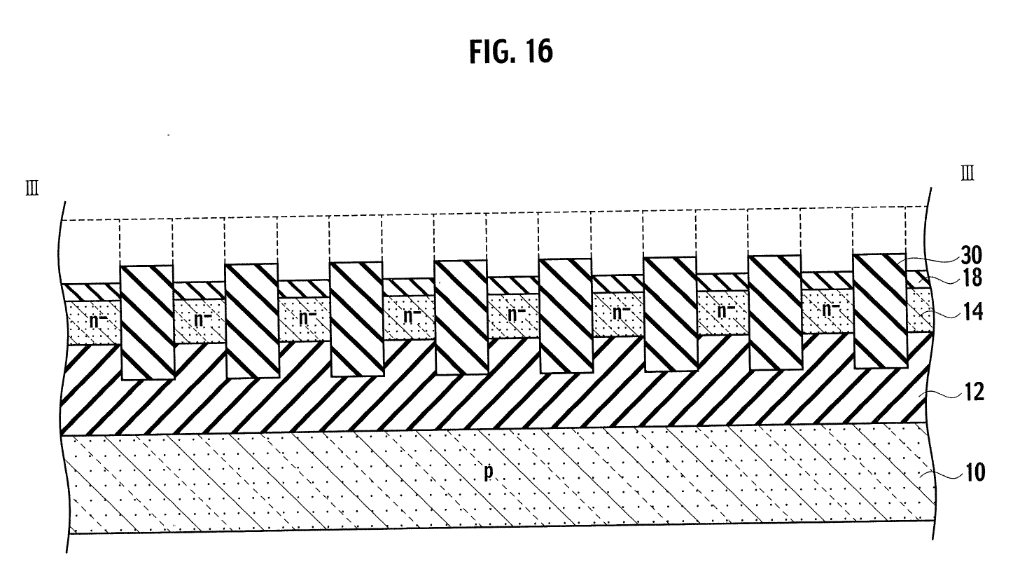

FIGS. 16, 17, 21, and 22 schematically showcross-sections of the nonvolatile semiconductor memory, according to the second embodiment of the present invention, cut along the line III-III of FIG. 12 describing process steps in the fabrication method thereof. In FIG. 12, line I-I denotes a section line extending along the column direction on the active region AA4, line II-II denotes a section line extending along the row direction on floating gates FG in between the control gate lines CG1 and CG2, and line III-III denotes a section line extending along the row direction on the control gate line CG4.

The memory cell transistors with the sidewall control gate structure in the nonvolatile semiconductor memory according to the second embodiment of the present invention are disposed adjacent to respective intersections of the plurality of active regions AA1, AA2, AA3, AA4, . . . , AA8, . . . , which extend along the column direction and are isolated from each other by STIs, and the plurality of control gate lines CG0, CG1, CG2, . . . , CG9, . . . , which extend along the row direction perpendicular to the plurality of active regions AA1, AA2, AA3, AA4, . . . , AA8, . . . .

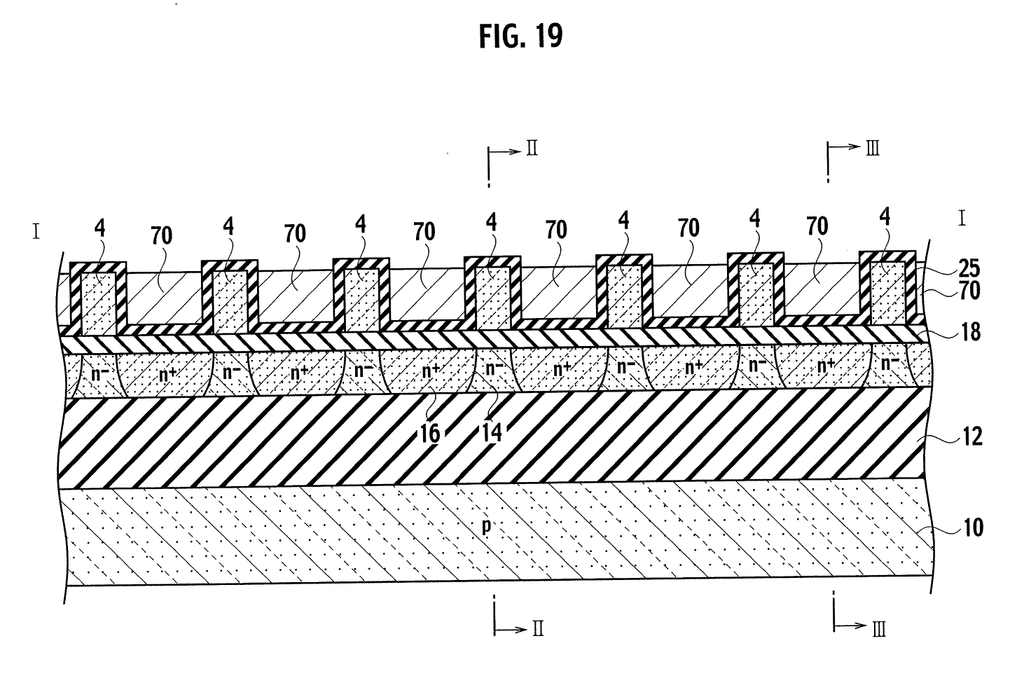

Each of the memory cell transistors is constituted by a semiconductor substrate 10, a SOI insulating layer 12 disposed in the semiconductor substrate 10, a SOI semiconductor layer 14 disposed on the SOI insulating layer 12, n⁺ source/drain regions 16 disposed facing each other in the SOI semiconductor layer 14, a tunneling insulating film 18 disposed on the SOI semiconductor layer 14, a floating gate polysilicon electrode layer 4 disposed on the tunneling insulating film 18, an inter-gate insulating film 25 disposed on the sidewalls of the floating gate polysilicon electrode layer 4 and the tunneling insulating film 18 on the source/drain regions, and a control gate metallic electrode layer 70 disposed facing the sidewalls of the floating gate polysilicon electrode layer 4 via the inter-gate insulating film 25, and disposed facing the n⁺ source/drain regions 16 via the tunneling insulating film 18 and the inter-gate insulating film 25, as shown in FIGS. 19 through 21 or 22.

FIG. 19 schematically shows a cross-section cut along the line I-I on the active region AA4 of FIG. 12, and thereby showing that the memory cell transistors with the sidewall control gate structure shown in FIG. 11 are aligned along the column direction, constituting a NAND column. The memory cell transistors with the sidewall control gate structure according to the second embodiment is different from the first embodiment of the present invention in that the floating gate polysilicon electrode layer 4 of each of the memory cell transistors is sandwiched between the control gate metallic electrode layer 70 via the inter-gate insulating film 25, and each of the control gate metallic electrode layer 70 is shared by adjacent memory cell transistors. Therefore, isolation of the memory cell transistors arranged along the column direction by interlayer insulating films 28 is unnecessary.

In FIG. 19, the control gate metallic electrode layer 70 running perpendicular to the page of FIG. 19 correspond to the plurality of control gate lines CG0, CG1, CG2, . . . , CG9, . . . shown in FIG. 12 or the plurality of control gate lines CG1, CG2, . . . , CG17 shown in FIG. 13.

FIG. 20 schematically shows a cross-section cut along the line II-II on the floating gates FG sandwiched between the control gate lines CG1 and CG2 of FIG. 12, and thus corresponds to the cross-section cut along the line II-II shown in FIG. 19. As is apparent from FIG. 20, the stacked structures of the respective memory cell transistors, each made up of the SOI semiconductor layer 14, the tunneling insulating film 18, and the floating gate polysilicon electrode layer 4, are isolated from each other by STIs 30. In the structures shown in FIG. 20, the bottoms of the STIs 30 are formed penetrating into the SOI insulating layer 12. The depth of the STIs can be adjusted so that the bottoms of the STIs 30 touch the surface of the SOI insulating layer 12 by adjusting the etching depth at the time of STI formation. Alternatively, the bottoms of the STIs 30 can be formed deep enough to reach the semiconductor substrate 10 through the SOI insulating layer 12. Namely, adjacent memory cell transistors formed on the plurality of active regions AA1, AA2, AA3, AA4, . . . , AA8, . . . extending along the column direction can be reliably isolated from each other along the row direction.

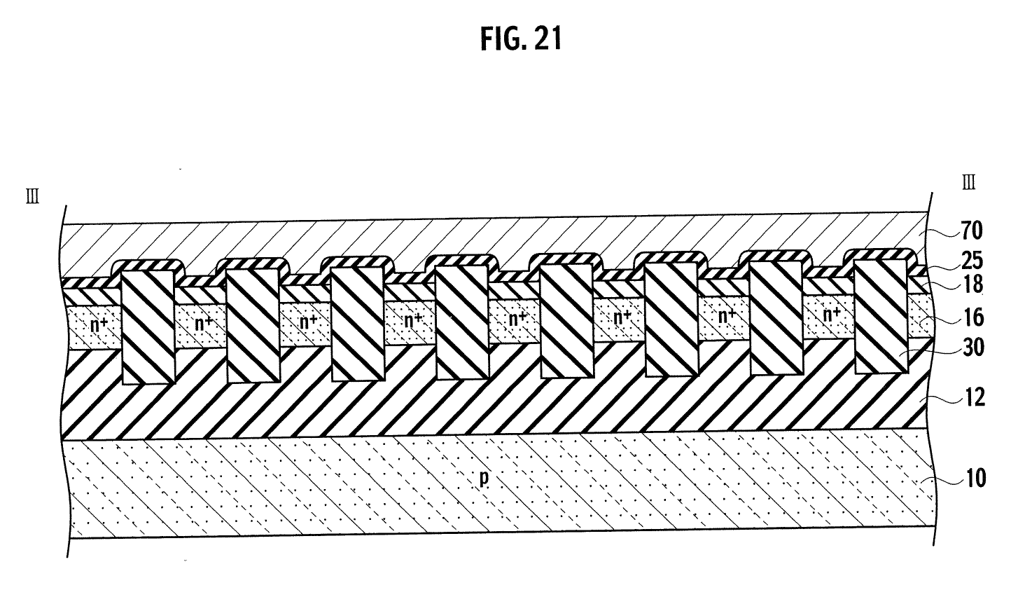

FIG. 21 schematically shows a cross-section, cut along the line III-III on the control gate line CG4 of FIG. 12, and thus corresponds to the cross-section, cut along the line III-III shown in FIG. 19. As is apparent from FIG. 21, the n⁺ source/drain regions 16 of the respective memory cell transistors and the tunneling insulating films 18 on the n⁺ source/drain regions 16 are isolated from each other by the STIs 30 along the line III-III.

Furthermore, the control gate metallic electrode layer 70 is arranged on the n⁺ source/drain regions 16 via the tunneling insulating films 18 and the inter-gate insulating film 25, extending along the row direction, as shown in FIG. 21.

In the structures shown in FIG. 21, the bottoms of the STIs 30 are formed penetrating into the SOI insulating layer 12. The depth of the STIs 30 can be adjusted so as for the bottoms of the STIs 30 to touch the surface of the SOI insulating layer 12 by adjusting the etching depth at the time of STI formation. Alternatively, the bottoms of the STIs 30 may be formed deep enough to reach the semiconductor substrate 10 through the SOI insulating layer 12. Namely, the n⁺ source/drain regions 16 of the respective memory cell transistors formed on the plurality of active regions AA1, AA2, AA3, AA4, . . . , AA8, . . . extending along the column direction may be reliably isolated from each other along the row direction.

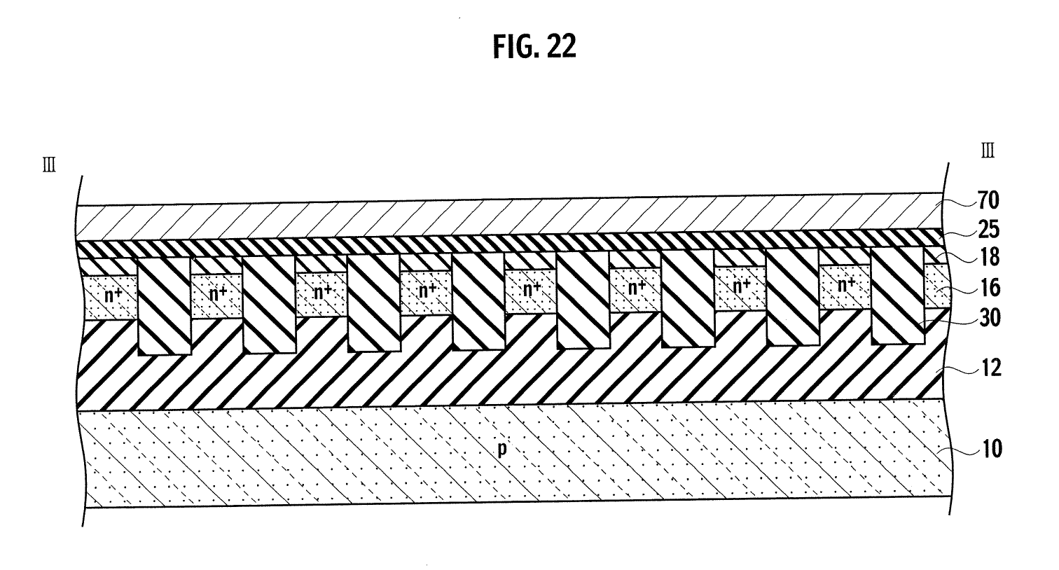

Furthermore, as is apparent from FIG. 22, another structure in which the control gate metallic electrode layer 70 is formed on the inter-gate insulating film (ONO film) 25, after depositing the inter-gate insulating film (ONO film) 25 on the entire planarized device surface including the tunneling insulating films 18 and the STIs 30, may be employed.

An arrangement of the buffer layer 26 on the inter-gate insulating film 25 and the control gate metallic electrode layer 70 on the buffer layer 26 can be realized even with the nonvolatile semiconductor memory according to the second embodiment of the present invention, as with the nonvolatile semiconductor memory according to the modified example of the first embodiment of the present invention. Providing the buffer layer 26 between the control gate metallic electrode layer 70 and the inter-gate insulating film 25 allows improvements in the adhesive characteristics between the control gate metallic electrode layer 70 and the inter-gate insulating film 25, and improvements in the reliability of the MIS structure made up of the control gate metallic electrode layer 70, the inter-gate insulating film 25, and the floating gate polysilicon electrode layer 4 or the n⁺ source/drain regions 16 in the sidewall control gate structure of the memory cell transistor, as shown in FIG. 11.

(Select Gate Transistor)

Select gate transistors SG1, SG2, and SG3 formed adjacent to the end of the series-connected sidewall control gate memory cell transistors disposed along the column direction, in the nonvolatile semiconductor memory according to the second embodiment of the present invention, are constituted by the semiconductor substrate 10; the SOI insulating layer 12 formed in the semiconductor substrate 10; the SOI semiconductor layer 14 formed on the SOI insulating layer 12; the n⁺ source/drain regions 16 disposed in the SOI semiconductor layer 14; the tunneling insulating film 18 disposed on the SOI semiconductor layer 14; the floating gate polysilicon electrode layer 4 disposed on the tunneling insulating film 18; the inter-gate insulating film 25 having openings on sidewalls of the floating gate polysilicon electrode layer 4 and disposed on sidewalls of the floating gate polysilicon electrode layer 4 and also disposed on the tunneling insulating film 18 on the n⁺ source/drain regions 16; and the control gate metallic electrode layer 70 disposed facing the n⁺ source/drain regions 16 and connected to the floating gate polysilicon electrode layer 4 via the inter-gate insulating film 25 having the openings on the sidewalls of the floating gate polysilicon electrode layer 4.

The select gate transistors formed as such correspond to transistors SG1, SG2, and SG3 having gate electrodes connected to the select gate lines SG01, SG02, and SG03, as shown in FIG. 13, respectively.

The select gate lines SG01, SG02, and SG03 becoming gate electrodes of the select gate transistors SG1, SG2, and SG3 and arranged in parallel to the plurality of control gate lines CG1, CG2, . . . , CG17, as shown in FIG. 13, may be formed in the same manner as the control gate metallic electrode layer 70.

Note that the gate structure of the select gate transistors is not limited to the above-described sidewall control gate structure. In order to secure the gate contacts of the select gate transistors, a contact electrode may be formed for the floating gate polysilicon electrode layer 4. The easiest method to secure the gate contacts of the select gate transistors is to form the gate electrode of the select gate transistors by short-circuiting the floating gate polysilicon electrode layer 4 with the control gate metallic electrode layer 70.

As described above, the structure connected at the sidewalls of the floating gate polysilicon electrode layers 4 can be easily and simply fabricated. Aside from this structure, a structure short-circuiting with the control gate metallic electrode layer 70 in the upper surface of the floating gate polysilicon electrode layers 4, for example, may be provided. Furthermore, instead of using the control gate metallic electrode layer 70, via hole contacts may be formed in the upper surface of the floating gate polysilicon electrode layers 4, connecting to other metallic electrodes for wirings than the control gate metallic electrode layer 70.

(Fabrication Method)

(a) First, as shown in FIG. 15, a SOI substrate made up of a semiconductor substrate 10, a SOI insulating layer 12 formed in the semiconductor substrate 10, and a SOI semiconductor layer 14 formed on the SOI insulating layer 12 are prepared; a tunneling insulating film 18 is formed on the SOI semiconductor layer 14; and a floating gate polysilicon electrode layer 4 is then formed on the tunneling insulating film 18.

Here, SiO₂, sapphire (Al₂O₃), or the like is available as the materials for the SOI insulating layer 12 that allows achievement of the SOI structure. Monocrystalline silicon, silicon germanium (SiGe), or the like is available as the materials for the SOI semiconductor layer 14 provided on the SOI insulating layer 12.

Although a silicon oxide film (SiO₂) is the typical material for the tunneling insulating film 18, silicon nitride (Si₃N₄), tantalum oxide (Ta₂O₅), titanium oxide (TiO₂), alumina (Al₂O₃), zirconium oxide (ZrO₂), or the like is also available.

(b) Next, as shown in FIG. 15, the floating gate polysilicon electrode layer 4 is patterned, the floating gate polysilicon electrode layer 4, the tunneling insulating film 18, the SOI semiconductor layer 14, and the SOI insulating layer 12 are etched and removed through the RIE techniques or the like, and a TEOS insulating film or the like is filled in and then planarized through the CMP techniques, thereby forming STIs 30.

(c) Next, as shown in FIG. 14, the floating gate polysilicon electrode layer 4 is patterned, etched, and removed through the RIE techniques, exposing the tunneling insulating film 18.

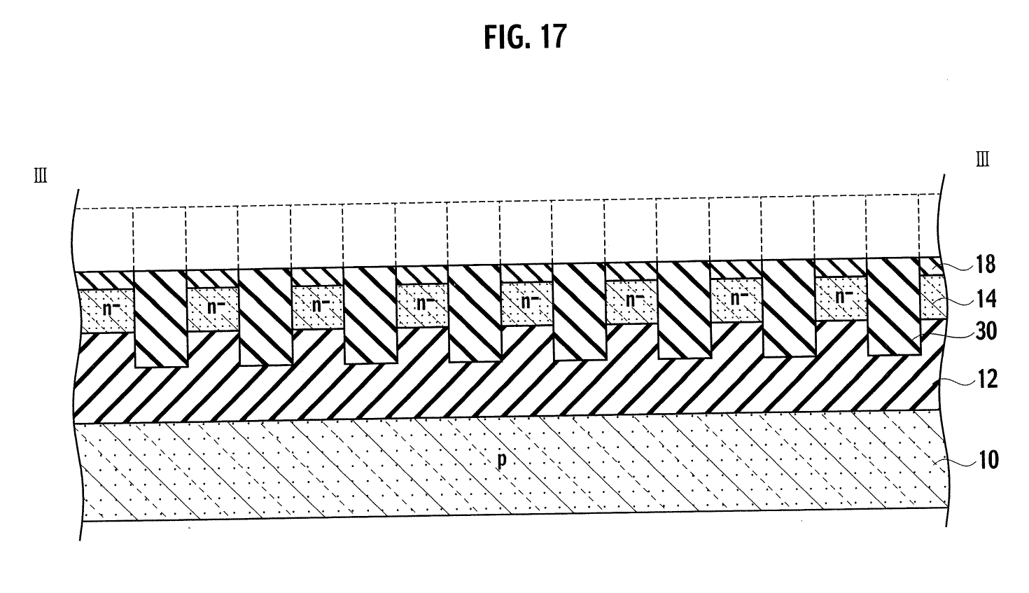

(d) Next, as shown in FIG. 16 or FIG. 17, the STIs 30 in which control gate lines are to be disposed are etched, forming a low surface height of the STIs 30. The surface height of the STIs 30 may be formed higher than the surface height of tunneling insulating film 18, as shown in FIG. 16. The surface height of the STIs 30 may alternatively be set to be approximately the same surface height as the tunneling insulating film 18, as shown in FIG. 17.

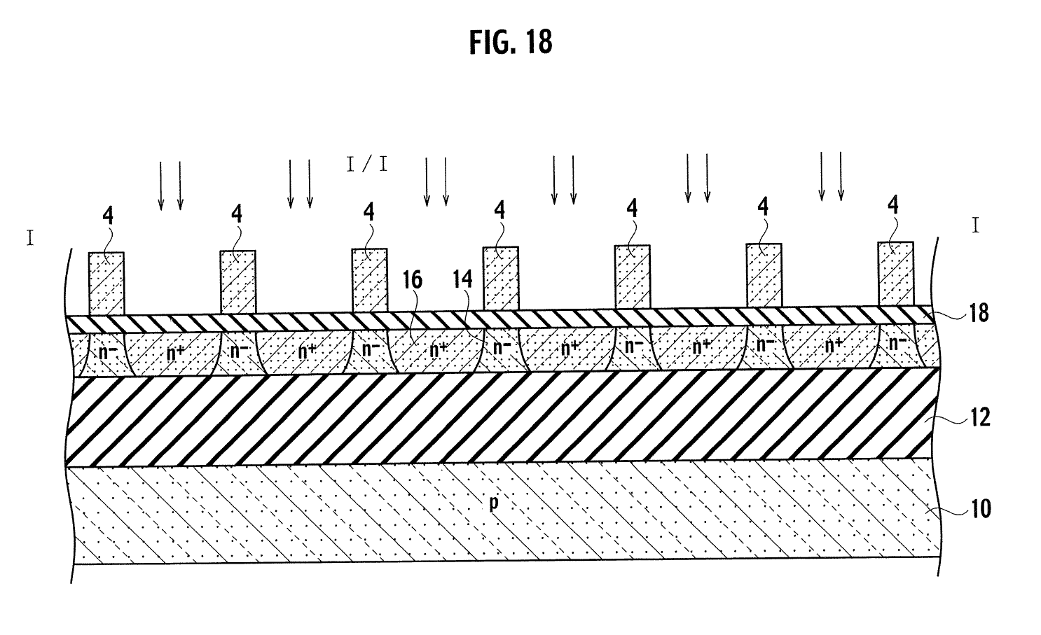

(e) Next, as shown in FIG. 18, with a predetermined accelerating energy and a predetermined amount of dosage, phosphorous (³¹P⁺) ions, arsenic (⁷⁵As⁺) ions, or the like are ion-implanted using ion implantation techniques and after an annealing process, n⁺ source/drain regions 16 are formed in the SOI semiconductor layer 14.

(f) Next, an inter-gate insulating film 25 is deposited across the entire semiconductor device surface.

As for the materials for the inter-gate insulating film 25, Si₃N₄, Ta₂O₅, TiO₂, Al₂O₃, ZrO₂, oxide-nitride-oxide (ONO), phosphorous Silicate glass (PSG), boron phosphorous silicate glass (BPSG), silicon oxinitride (SiON), barium titanium oxide (BaTiO₃), acid silicon fluoride (SiOₓF_{y}), an organic resin such as a polyimide, or the like is available.

(g) A control gate metallic electrode layer 70 is then deposited across the entire semiconductor device surface.

(h) Next, as shown in FIGS. 19 through 22, the entire semiconductor device surface is planarized through the CMP techniques until the inter-gate insulating film 25 is exposed, and as a result, the control gate metallic electrode layer 70 is filled in and formed sandwiched by the inter-gate insulating films 25 on both sides through a metal damascene process.

As a result, the control gate metallic electrode layer 70 extending along the row direction are filled in and formed in a stripe form along the row direction, forming a plurality of control gate lines CG0, CG1, CG2, . . . , CG17.

The control gate metallic electrode layer 70 corresponds to control gate lines and thus may be constituted using a metallic silicide film. Silicide material such as Cobalt (Co), Nickel (Ni), Titanium (Ti), Tantalum (Ta), Platinum (Pt), Molybdenum (Mo), Tungsten (W), Palladium (Pd), or the like, for example, may be applied as the material for the metallic silicide film.

The fabrication method for the nonvolatile semiconductor memory, according to the second embodiment of the present invention, having the sidewall control gate structure, which is fabricated by forming the floating gates with polysilicon and then forming the control gates with metallic electrode layers, has been described. Descriptions for the subsequent process steps are omitted since a plurality of bit lines and peripheral circuit interconnect wirings are formed through a typical interconnect wirings/contacts formation process.

According to the second embodiment of the nonvolatile semiconductor memory and the fabrication method for the same, using a metal damascene process in the formation of the control gate electrode layer in a memory cell transistor having the sidewall control gate structure allows reduction in the aspect ratio of the sidewall control gate structure, implementation of simpler processing and reduction in the value of parasitic capacitances between adjacent cells, miniaturization, higher integration, and simpler processing of a memory cell array, and low power consumption and higher speed operability of the nonvolatile semiconductor memory.

### Third Embodiment

(Basic Structure)

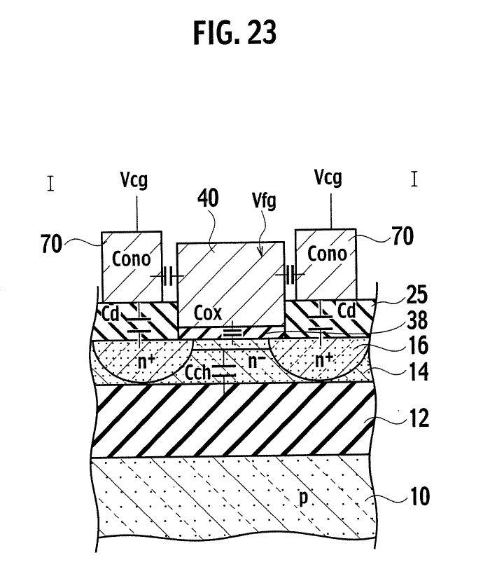

The basic structure of a memory cell transistor in a nonvolatile semiconductor memory according to the third embodiment of the present invention is, as shown in FIG. 23, a sidewall control gate structure including a SOI insulating layer 12 formed in a semiconductor substrate 10; a SOI semiconductor layer 14 formed on the SOI insulating layer 12; n⁺ source/drain regions 16 disposed facing each other in the SOI semiconductor layer 14; a tunneling insulating film 38 disposed on the SOI semiconductor layer 14 sandwiched between the n⁺ source/drain regions 16; a floating gate metallic electrode layer 40 disposed on the tunneling insulating film 38; inter-gate insulating films 25 disposed on the sidewalls of the floating gate metallic electrode layer 40 and disposed on the n⁺ source/drain regions 16; and control gate metallic electrode layer 70 formed facing the n⁺ source/drain regions 16 via the inter-gate insulating films 25 and formed facing the sidewalls of the floating gate metallic electrode layer 40 via the inter-gate insulating films 25. FIG. 23 corresponds to a memory cell transistor structure in the cross-section of an active region AA4 cut along the line I-I in the column direction in a plan view pattern structure, as shown in FIG. 12.

According to the sidewall control gate structure, as with the second embodiment, the parasitic capacitances around the floating gate metallic electrode layer 40 can be reduced, and an amount of increase in the value of the capacitance between the control gate metallic electrode layer 70 and the floating gate metallic electrode layer 40 allows an amount of decrease in the value of write-in voltage V_{pgm}. As a result, a highly integrated nonvolatile semiconductor memory, which is capable of operating at high speed, can be realized.

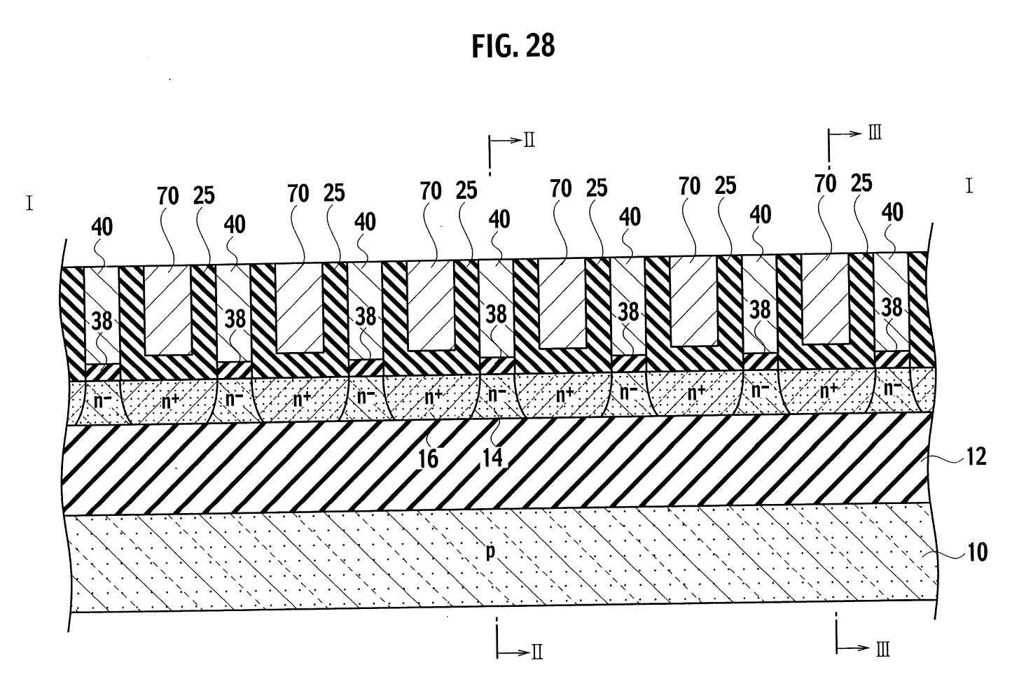

Furthermore, according to the nonvolatile semiconductor memory of the third embodiment of the present invention, miniaturization of fine patterns of memory cell transistors and a thin gate structure realizing a low aspect ratio can be further facilitated using metal damascene processes for both the floating gate metallic electrode layer 40 and the control gate metallic electrode layer 70, as shown in FIG. 28.

(NAND Circuit Structure)

The matrix circuit structure of the nonvolatile semiconductor memory according to the third embodiment of the present invention is presented as with the second embodiment, for example. In other words, as shown in FIG. 13, the matrix circuit structure of the nonvolatile semiconductor memory is constituted by six NAND memory cell units 29a through 29f, a plurality of control gate lines CG1 through CG17, a plurality of select gate lines SG01 through SG03, a plurality of bit lines . . . , BLk−1, BLk, and BLk+1, . . . , a source line SL, a plurality of bit line driver circuits 21, a plurality of control gate line driver circuits 20, a plurality of select gate line driver circuits 23, and a source line driver circuit 24. In the example of FIG. 13, the NAND memory cell units 29a through 29f, each including sixteen serially connected memory cell transistors, one bit line side select gate transistor SG1 or SG2 disposed adjacent to the control gate line CG17, and one source line side select gate transistor SG3 disposed adjacent to the control gate line CG1.

The sixteen serially connected memory cell transistors in the NAND memory cell units 29a through 29f are connected to the respective bit lines . . . , BLk−1, BLk, and BLk+1, . . . via the select gate transistors SG1 or SG2 and a source line SL via the select gate transistors SG3. Furthermore, in FIG. 13, a row of memory cells corresponding to one page in page mode may be defined by all the memory cell transistors 27 sandwiched between the two control gate lines CG12 and CG13, for example.

Note that as with the first and the second embodiment, the memory cell transistors may be a depletion mode MIS transistor by including a channel region with the same conductivity as the n⁺ source/drain regions 16. Alternatively, each of the memory cell transistors may be an enhancement mode MIS transistor by including a channel region with the opposite conductivity to that of the n⁺source/drain regions 16.

(Plan View Pattern Structure)

A plan view pattern structure of the nonvolatile semiconductor memory according to the third embodiment of the present invention is presented in FIG. 12, as with the second embodiment.

The nonvolatile semiconductor memory according to the third embodiment of the present invention has a plurality of memory cell transistors arranged in a matrix on a SOI insulating layer 12, as shown in FIGS. 23 and 12. The nonvolatile semiconductor memory according to the third embodiment of the present invention includes a plurality of active regions AA1, AA2, AA3, AA4, . . . , AA8, . . . extending along the column direction isolated from each other by STIs, and a plurality of control gate lines CG0, CG1, CG2, . . . , CG17 extending along the row direction perpendicular to the plurality of active regions AA1, AA2, AA3, AA4, . . . , AA8, . . . .

Moreover, the nonvolatile semiconductor memory according to the third embodiment of the present invention includes, as shown in FIGS. 23 and 12, the memory cell transistors MC, each having a floating gate FG, disposed sandwiched between adjacent control gate lines on the intersections of the plurality of active regions AA1, AA2, AA3, AA4, . . . , AA8, . . . and the plurality of control gate lines CG0, CG1, CG2, . . . , CG17.

(Device Structure)

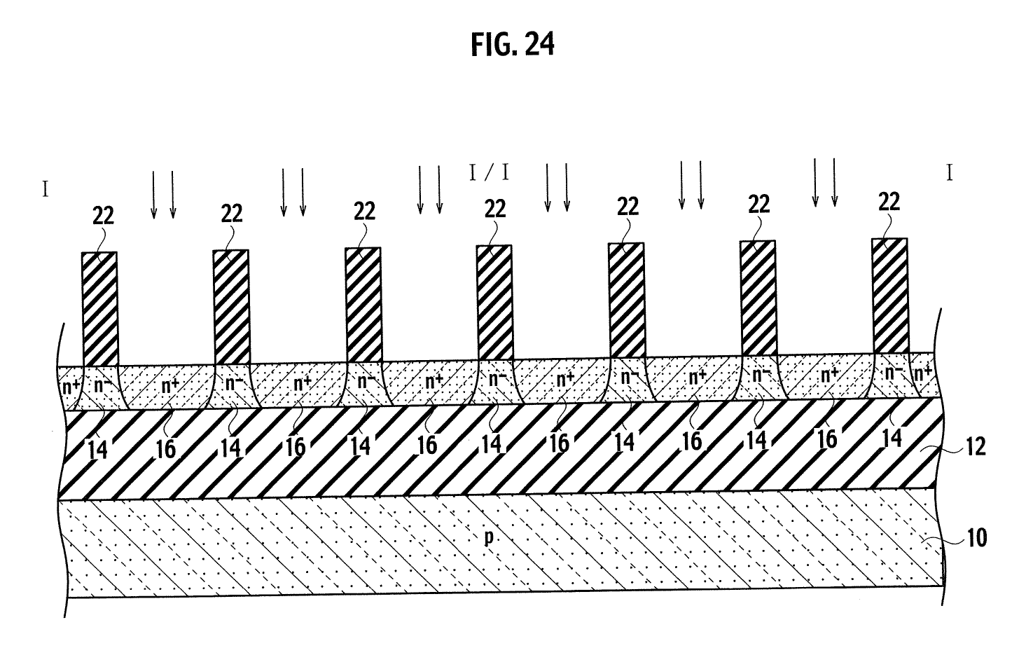

FIGS. 24 through 28 are cross-sections of the nonvolatile semiconductor memory, according to the third embodiment of the present invention, cut along the line I-I of FIG. 12 schematically showing process steps in a fabrication method thereof.

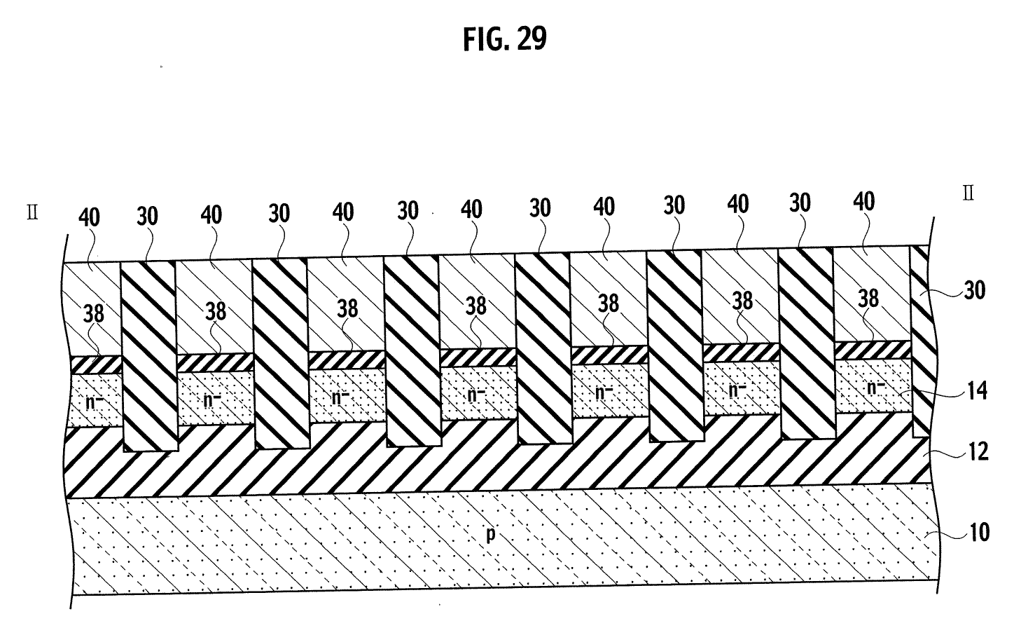

FIG. 29 is a cross-section of the nonvolatile semiconductor memory, according to the third embodiment of the present invention, cut along the line II-II of FIG. 12 schematically showing a process step in the fabrication method thereof.

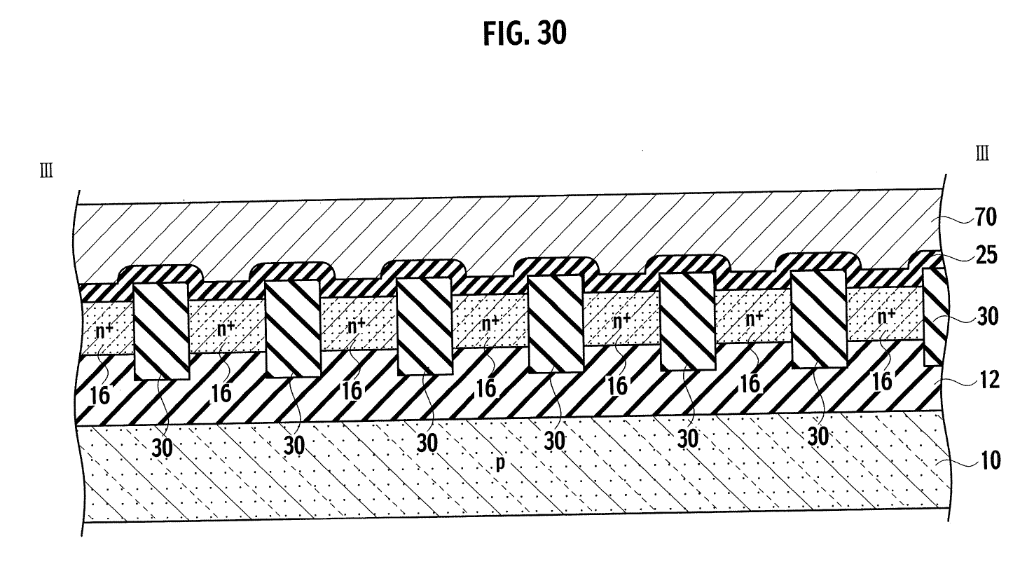

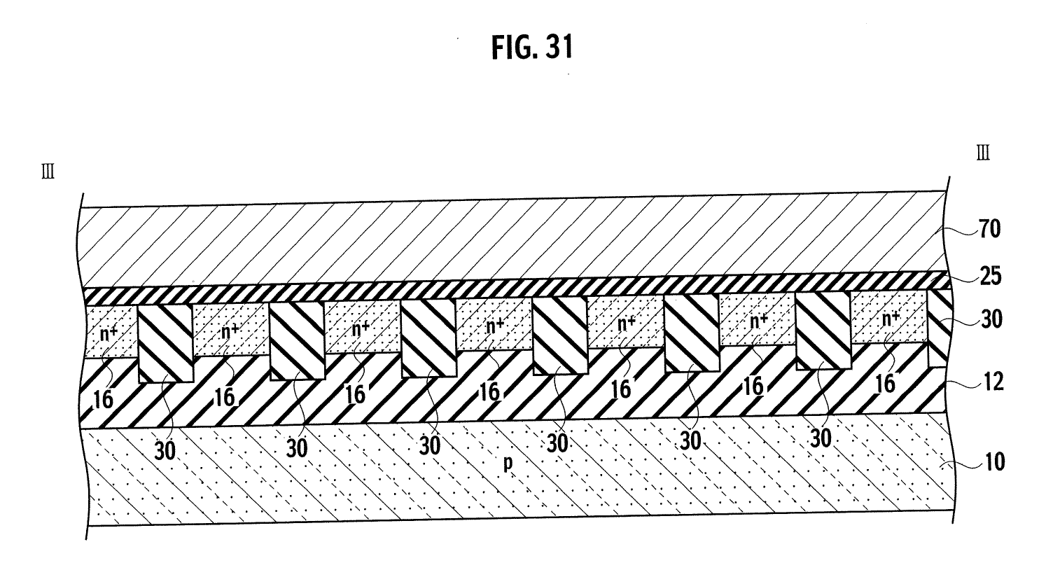

FIGS. 30 and 31 are cross-sections of the nonvolatile semiconductor memory, according to the third embodiment of the present invention, cut along the line III-III of FIG. 12 schematically showing process steps in the fabrication method thereof.

The memory cell transistors with the sidewall control gate structure in the nonvolatile semiconductor memory, according to the third embodiment of the present invention, are disposed adjacent to respective intersections of the plurality of active regions AA1, AA2, AA3, AA4, . . . , AA8, . . . , which extend along the column direction and are isolated from each other by STIs, and the plurality of control gate lines CG0, CG1, CG2, . . . , CG9, . . . , which extend along the row direction perpendicular to the plurality of active regions AA1, AA2, AA3, AA4, . . . , AA8, . . . .

Each of the memory cell transistors with the sidewall control gate structure includes: a semiconductor substrate 10; a SOI insulating layer 12 disposed in the semiconductor substrate 10; a SOI semiconductor layer 14 disposed on the SOI insulating layer 12; n⁺ source/drain regions 16 disposed facing each other in the SOI semiconductor layer 14; a tunneling insulating film 38 disposed on the SOI semiconductor layer 14 sandwiched between the n⁺ source/drain regions 16; a floating gate metallic electrode layer 40 disposed on the tunneling insulating film 38; an inter-gate insulating film 25 disposed on the sidewalls of the floating gate metallic electrode layer 40 and the source/drain regions 16; and a control gate metallic electrode layer 70 disposed facing the n⁺ source/drain regions 16 via the inter-gate insulating film 25 and facing the sidewalls of the floating gate metallic electrode layer 40 via the inter-gate insulating film 25, as shown in FIGS. 28 through 30 or in FIG. 31.

FIG. 28 schematically shows a cross-section cut along the line I-I on the active region AA4 of FIG. 12, and thereby showing that the memory cell transistors with the sidewall control gate structure shown in FIG. 23 are aligned extending along the column direction, constituting a NAND column. The memory cell transistors with the sidewall control gate structure according to the third embodiment is different from the first embodiment of the present invention in that each of the floating gate metallic electrode layers 40 of the respective memory cell transistors is sandwiched between the control gate metallic electrode layer 70 via the inter-gate insulating films 25, and is used in common by the memory cell transistors adjacent to the control gate metallic electrode layer 70. Therefore, isolation of the memory cell transistors arranged along the column direction by interlayer insulating films 28 is unnecessary.

In FIG. 28, the control gate metallic electrode layer 70 running perpendicular to the page correspond to the control gate lines CG0, CG1, CG2, . . . , CG9, . . . shown in FIG. 12 or the control gate lines CG1, CG2, . . . , CG17 shown in FIG. 13.

FIG. 29 schematically shows a cross-section cut along the line II-II on the floating gates FG sandwiched between the control gate lines CG1 and CG2 of FIG. 12, and thus corresponds to the cross-section cut along the line II-II shown in FIG. 28. As is apparent from FIG. 29, the stacked structures made up of the SOI semiconductor layers 14, the tunneling insulating films 38, and the floating gate metallic electrode layers 40 of the respective memory cell transistors are isolated from each other by STIs 30. In the structures shown in FIG. 29, the bottoms of the STIs 30 are formed penetrating into the SOI insulating layer 12. The depth of the STIs can be adjusted so that the bottoms of the STIs 30 touch the surface of the SOI insulating layer 12 by adjusting the etching depth at the time of STI formation. Alternatively, the bottoms of the STIs 30 may be formed deep enough to reach the semiconductor substrate 10 through the SOI insulating layer 12. Namely, adjacent memory cell transistors formed on the plurality of active regions AA1, AA2, AA3, AA4, . . . , AA8, . . . extending along the column direction can be reliably isolated from each other along the row direction.

FIG. 30 schematically shows a cross-section, cut along the line III-III on the control gate line CG4 of FIG. 12, and thus corresponds to the cross-section, cut along the line III-III shown in FIG. 28. As is evident from FIG. 30, the n⁺ source/drain regions 16 of the respective memory cell transistors are isolated from each other by the STIs 30 along the line III-III.

Furthermore, the control gate metallic electrode layer 70 is arranged extending along the row direction on the n⁺ source/drain regions 16 via the inter-gate insulating film 25, as shown in FIG. 30.

In the structures shown in FIG. 30, the bottoms of the STIs 30 are formed penetrating into the SOI insulating layer 12. The depth of the STIs can be adjusted so that the bottoms of the STIs 30 touch the surface of the SOI insulating layer 12 by adjusting the etching depth at the time of STI formation. Alternatively, the bottoms of the STIs 30 may be formed deep enough to reach the semiconductor substrate 10 through the SOI insulating layer 12. Namely, the n⁺ source/drain regions 16 of adjacent memory cell transistors formed on the plurality of active regions AA1, AA2, AA3, AA4, . . . , AA8, . . . extending along the column direction may be reliably isolated from each other along the row direction.

Furthermore, as is apparent from FIG. 31, another structure in which the control gate metallic electrode layer 70 is formed on the inter-gate insulating film (ONO film) 25, after depositing the inter-gate insulating film (ONO film) 25 on the entire planarized device surface including the tunneling insulating films 38 and the STIs 30, may be employed.

An arrangement of the buffer layer 26 on the inter-gate insulating film 25 and the control gate metallic electrode layer 70 on the buffer layer 26 can be realized even with the nonvolatile semiconductor memory according to the third embodiment of the present invention, as with the nonvolatile semiconductor memory according to the modified example of the first embodiment of the present invention. Providing the buffer layer 26 between the control gate metallic electrode layer 70 and the inter-gate insulating film 25 allows improvements in the adhesive characteristics between the control gate metallic electrode layer 70 and the inter-gate insulating film 25, and improvements in reliability of the MIS structure made up of the control gate metallic electrode layer 70, the inter-gate insulating film 25, and the floating gate metallic electrode layers 40 or the n⁺ source/drain regions 16 in the sidewall control gate structure of the memory cell transistor, as shown in FIG. 23.

(Select Gate Transistor)

The select gate transistors SG1, SG2, and SG3 formed adjacent to the end of the series-connected sidewall control gate memory cell transistors disposed along the column direction, in the nonvolatile semiconductor memory according to the third embodiment of the present invention, can be formed in the same way as in the second embodiment. For example, the select gate transistors SG1, SG2, and SG3 are constituted by the semiconductor substrate 10; the SOI insulating layer 12 formed in the semiconductor substrate 10; the SOI semiconductor layers 14 formed on the SOI insulating layer 12; the n⁺ source/drain regions 16 disposed facing each other in the SOI semiconductor layers 14; the tunneling insulating films 38, each disposed on the SOI semiconductor layers 14 sandwiched between the n⁺ source/drain regions 16; the floating gate metallic electrode layer 40 disposed on the tunneling insulating films 38; the inter-gate insulating film 25 having openings disposed on the sidewalls of the floating gate metallic electrode layer 40 and disposed on the n⁺ source/drain regions 16; and the control gate metallic electrode layer 70 formed facing the n⁺ source/drain regions 16 via the inter-gate insulating film 25 and connected to the floating gate metallic electrode layers 40 via the inter-gate insulating film 25 having the openings on the sidewalls of the floating gate metallic electrode layer 40.

The select gate transistors formed as such correspond to transistors SG1, SG2, and SG3 having gate electrodes connected to the select gate lines SG01, SG02, and SG03, as shown in FIG. 13, respectively.

The select gate lines SG01, SG02, and SG03 becoming gate electrodes of the select gate transistors and arranged in parallel to the plurality of control gate lines CG1, CG2, . . . , CG17, as shown in FIG. 13, may be formed in the same manner as the control gate metallic electrode layer 70.

Note that the gate structure of the select gate transistors is not limited to the above-described sidewall control gate structure. In order to secure the gate contacts of the select gate transistors, a contact electrode may be formed for the floating gate metallic electrode layer 40. The easiest method to secure the gate contacts of the select gate transistors is to form the gate electrode of the select gate transistors by short-circuiting the floating gate metallic electrode layers 40 with the control gate metallic electrode layer 70.

As described above, the structure connected at the sidewalls of the floating gate metallic electrode layers 40 can be easily and simply fabricated. Aside from this structure, a structure short-circuiting with the control gate metallic electrode layer 70 in the upper surface of the floating gate metallic electrode layers 40, for example, may be provided. Furthermore, instead of using the control gate metallic electrode layer 70, via hole contacts may be formed in the upper surface of the floating gate metallic electrode layers 40, connecting to other metallic electrodes for wirings than the control gate metallic electrode layer 70.

(Fabrication Method)

(a) First, a SOI substrate made up of a semiconductor substrate 10, a SOI insulating layer 12 formed in the semiconductor substrate 10, and a SOI semiconductor layer 14 formed on the SOI insulating layer 12 are prepared, and a nitride film 22 is formed on the SOI semiconductor layer 14.

Here, SiO₂, sapphire (Al₂O₃), or the like is available as the materials for the SOI insulating layer 12 achieving the SOI structure. Monocrystalline silicon, silicon germanium (SiGe), or the like is available as the materials for the SOI semiconductor layer 14 provided on the SOI insulating layer 12.

(b) Next, the nitride film 22 is patterned, the nitride film 22, the SOI semiconductor layer 14, and the SOI insulating layer 12 are etched and removed through the RIE techniques or the like, a TEOS insulating film or the like is filled in and then planarized through the CMP techniques, thereby forming STIs 30. As a result, the STIs 30 are formed in other areas than the plurality of active regions AA1, AA2, AA3, AA4, . . . , AA8, . . . , as shown in FIG. 12.

(c) Next, the nitride film 22 is patterned, etched, and removed through the RIE techniques, exposing the SOI semiconductor layer 14.

(d) Next, the STIs 30 in which control gate lines are to be disposed are etched, providing a low surface height of STIs 30. The surface height of the STIs 30 may be formed higher than the surface height of the SOI semiconductor layer 14. The surface height of the STIs 30 may alternatively be formed to be approximately the same surface height as the SOI semiconductor layer 14.

(e) Next, as shown in FIG. 24, with a predetermined accelerating energy and a predetermined amount of dosage,phosphorous (³¹P⁺) ions, arsenic (⁷⁵As⁺) ions, or the like are ion-implanted using ion-implantation techniques, and after an annealing process, n⁺ source/drain regions 16 are formed in the SOI semiconductor layer 14.

(f) Next, an inter-gate insulating film 25 is deposited across the entire semiconductor device surface.

As for the materials for the inter-gate insulating film 25, Si₃N₄, Ta₂O₅, TiO₂, Al₂0₃, ZrO₂, oxide-nitride-oxide (ONO), phosphorous silicate glass (PSG), boron phosphorous silicate glass (BPSG), silicon oxinitride (SiON), barium titanium oxide (BaTiO₃), acid silicon fluoride (SiOₓF_{y}), an organic resin such as a polyimide, or the like is available.

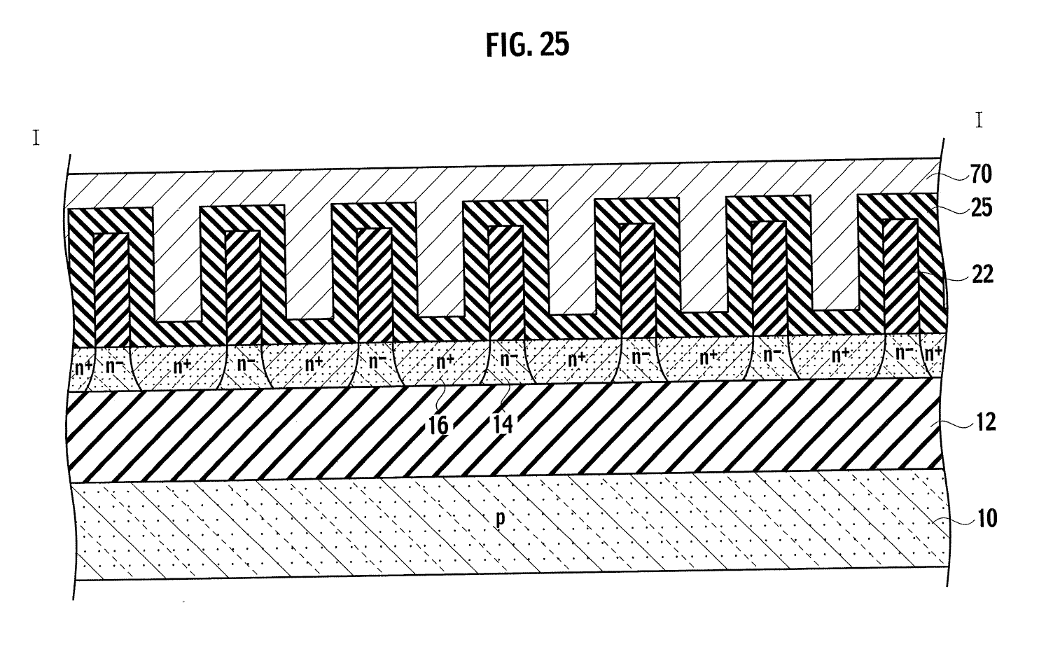

(g) A control gate metallic electrode layer 70 is then deposited across the entire semiconductor device surface, as shown in FIG. 25.

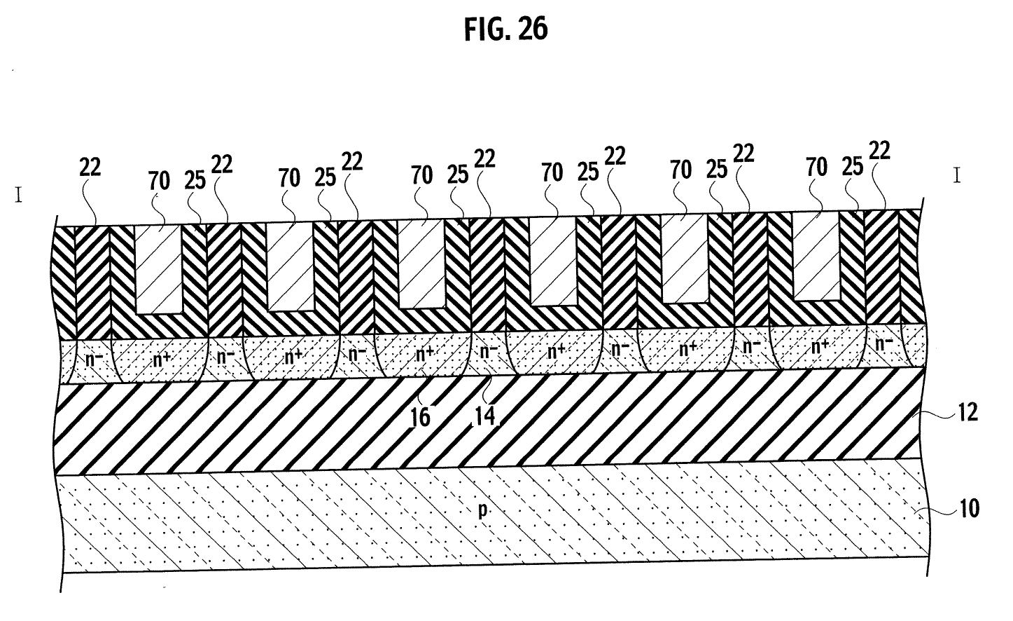

(h) Next, as shown in FIG. 26, the entire semiconductor device surface is planarized through the CMP techniques until the surface of the inter-gate insulating films 25 and the nitride films 22 are exposed, and as a result, the control gate metallic electrode layer 70 is filled in and formed sandwiched by adjacent inter-gate insulating films 25 on both sides through a metal damascene process.

As a result, the control gate metallic electrode layer 70 extending along the row direction are filled in and formed in a stripe form along the row direction, forming a plurality of control gate lines CG0, CG1, CG2, . . . , CG17.

The control gate metallic electrode layer 70 corresponds to control gate lines and thus may be constituted using a metallic silicide film. Silicide material such as Cobalt (Co), Nickel (Ni), Titanium (Ti), Tantalum (Ta), Platinum (Pt), Molybdenum (Mo), Tungsten (W), Palladium (Pd), or the like may be applied as the material to form the metallic silicide film.

(i) Next, the nitride film 22 is patterned, etched, and removed through the RIE techniques, exposing the surface of the SOI semiconductor layer 14.

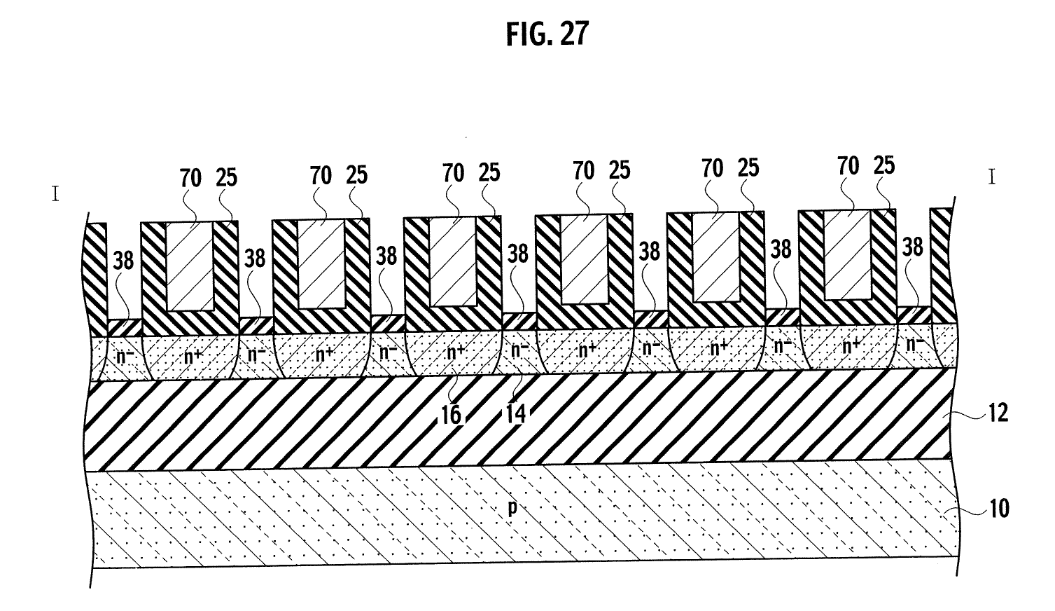

(j) Next, as shown in FIG. 27, the tunneling insulating film 38 is formed on the exposed surface of the SOI semiconductor layer 14.

Although a silicon oxide film (SiO₂) such as a thermal-oxidation film or an insulating film formed at a low temperature CVD is the typical material for the tunneling insulating film 38, silicon nitride (Si₃N₄), tantalum oxide (Ta₂O₅), titanium oxide (TiO₂), alumina (Al₂O₃), zirconium oxide (ZrO₂), or the like is also available.

(k) A floating gate metallic electrode layer 40 is then deposited across the entire semiconductor device surface.

(l) Next, as shown in FIG. 28, the entire semiconductor device surface is planarized through the CMP techniques until the surface of the inter-gate insulating films 25 and the nitride films 22 are exposed, and as a result, the floating gate metallic electrode layer 40 is filled in and formed sandwiched by adjacent inter-gate insulating films 25 on both sides through a metal damascene process.

While the floating gate metallic electrode layers 40 correspond to charge accumulating layers of the memory cell transistors constituting the nonvolatile semiconductor memory, the floating gate metallic electrode layers 40 may be constituted using a metallic silicide film. Silicide material such as Cobalt (Co), Nickel (Ni), Titanium (Ti), Tantalum (Ta), Platinum (Pt), Molybdenum (Mo), Tungsten (W), Palladium (Pd), or the like may be applied as the material to form the metallic silicide film.

The fabrication method for the nonvolatile semiconductor memory, according to the third embodiment of the present invention, having the sidewall control gate structure, which is fabricated by forming the floating gates and the control gates using metallic electrode layers, has been described. Descriptions for the subsequent process steps are omitted since a plurality of bit lines and peripheral circuit interconnect wirings are formed through a typical interconnect wirings/contacts formation process.

According to the third embodiment of the nonvolatile semiconductor memory of the present invention and the fabrication method for the same, using the metal damascene processes in the formation of the metallic electrode layers of both control gates and floating gates in the memory cell transistor with the sidewall control gate structure allows reduction in the aspect ratio, implementation of simpler processing and reduction in the value of parasitic capacitances between adjacent cells, miniaturization, higher integration, and simpler processing of a memory cell array, and low power consumption and higher speed operability of the nonvolatile semiconductor memory.

Applications

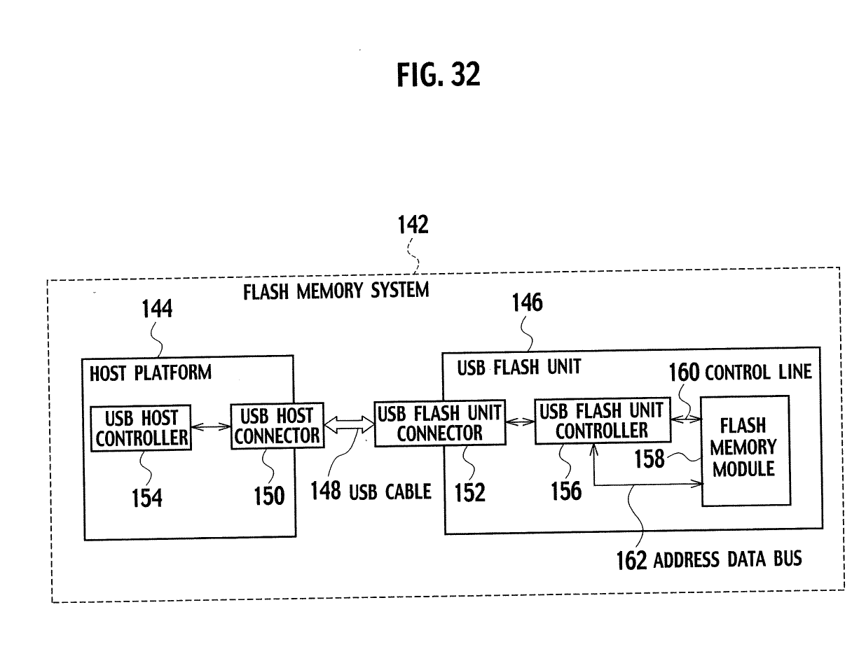

The nonvolatile semiconductor memory according to the first through the third embodiment of the present invention may be applied in various ways. Some of these applications are shown in FIGS. 32 through 38.

In the application examples of the nonvolatile semiconductor memory according to the first through the third embodiment of the present invention and the fabrication method for the same, using of a metal damascene process in the formation of the metallic electrode layers of either or both control gates and floating gates in the memory cell transistor allows reduction in the aspect ratio, implementation of simpler processing and reduction in the value of parasitic capacitances between adjacent cells, miniaturization, higher integration, and simpler processing of a memory cell array, and low power consumption and higher speed operability of not only the nonvolatile semiconductor memory but of the apparatus according to the application examples including peripheral circuits.

(Application 1)

FIG. 32 is a schematic block diagram of principle elements of a flash memory device and system. As shown in FIG. 32, a flash memory system 142 is configured with a host platform 144 and a universal serial bus (USB) flash unit 146.

The host platform 144 is connected to the USB flash unit 146 via a USB cable 148. The host platform 144 is connected to the USB cable 148 via a USB host connector 150, and the USB flash unit 146 is connected to the USB cable 148 via a USB flash unit connector 152. The host platform 144 has a USB host controller 154, which controls packet transmission through a USB bus.

The USB flash unit 146 includes a USB flash unit controller 156, which controls other elements in the USB flash unit 146 as well as controls the interface to the USB bus of the USB flash unit 146; the USB flash unit connector 152; and at least one flash memory module 158 configured with the nonvolatile semiconductor memory according to the first through the third embodiment of the present invention.

When the USB flash unit 146 is connected to the host platform 144, standard USB enumeration processing begins. In this processing, the host platform 144 recognizes the USB flash unit 146, selects the mode for transmission therewith, and performs reception/transmission of data from/to the USB flash unit 146 via a FIFO buffer called an end point, which stores transfer data. The host platform 144 recognizes changes in the physical and electrical states such as removal/attachment of the USB flash unit 146 via another end point, and receives any existing to-be-received packets.

The host platform 144 requests services from the USB flash unit 146 by sending a request packet to the USB host controller 154. The USB host controller 154 transmits the packet to the USB cable 148. If the USB flash unit 146 is a unit including the end point that has received this request packet, this request will be accepted by the USB flash unit controller 156.

Next, the USB flash unit controller 156 performs various operations such as read-out, write-in or erasure of data from or to the flash memory module 158. In addition, it supports basic USB functions such as acquiring a USB address and the like. The USB flash unit controller 156 controls the flash memory module 158 via either a control line 160, which is used to control output of the flash memory module 158, or, for example, other various signals such as a chip enable signal CE, a read-out signal, or a write-in signal. Furthermore, the flash memory module 158 is also connected to the USB flash unit controller 156 via an address data bus 162. The address data bus 162 transfers a read-out, a write-in or an erasure command for the flash memory module 158, and the address and data for the flash memory module 158.

In order to notify the host platform 144 of the results and status of the various operations requested by the host platform 144, the USB flash unit 146 transmits a status packet using a status end point (end point 0). In this processing, the host platform 144 checks (polls) for the existence of a status packet, and the USB flash unit 146 returns an empty packet or a status packet when there is no packet for a new status message.

As described thus far, various functions of the USB flash unit 146 maybe implemented. Directly connecting the connectors is also possible by omitting the USB cable 148 described above.

(Memory Card)

(Application 2)

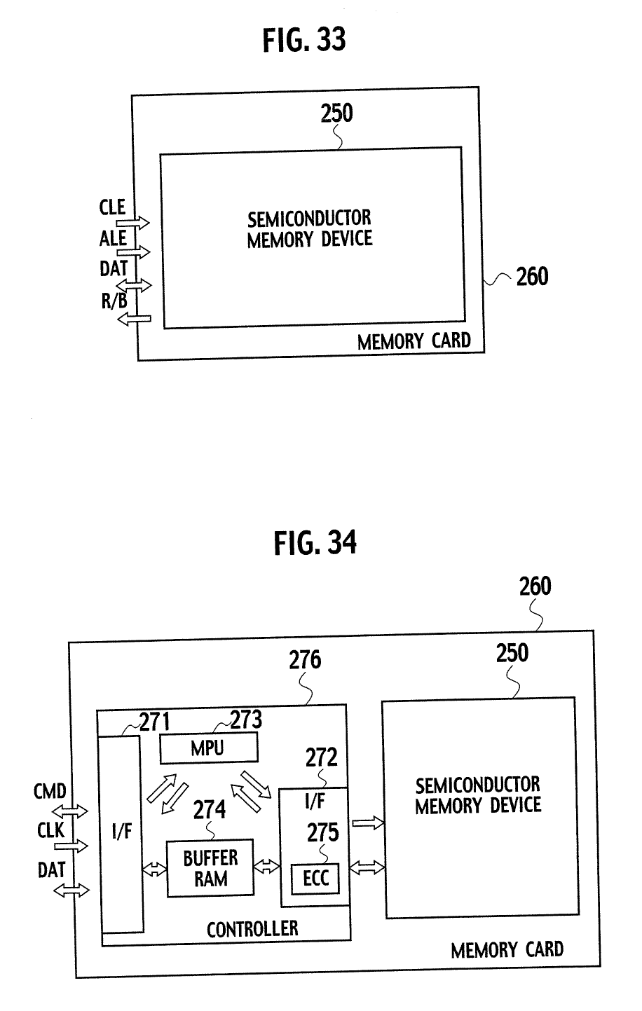

As an example, a memory card 260 including a semiconductor memory device 250 is configured as shown in FIG. 33. The nonvolatile semiconductor memory according to the first through the third embodiment of the present invention may be applied to the semiconductor memory device 250. The memory card 260 may operate so as to receive a predetermined signal from an external device (not shown in the drawing), or output a predetermined signal to the external device, as shown in FIG. 33.

A signal line DAT, a command line enable signal line CLE, an address line enable signal line ALE, and a ready/busy signal line R/B are connected to the memory card 260 housing the semiconductor memory device 250. The signal line DAT transfers a data signal, an address signal, or a command signal. The command line enable signal line CLE transmits a signal indicating that a command signal is being transferred over the signal line DAT. The address line enable signal line ALE transmits a signal indicating that an address signal is being transferred over the signal line DAT. The ready/busy signal line R/B transmits a signal indicating whether or not the semiconductor memory device 250 is ready to operate.

(Application 3)

Another specific example of the memory card 260 differs from the exemplary memory card of FIG. 33, including a controller 276 configured to control the semiconductor memory device 250 and transmit and receive predetermined signals to and from an external device, as shown in FIG. 34, in addition to the semiconductor memory device 250. The controller 276 includes an interface unit (I/F) 271, a microprocessor unit (MPU) 273, a buffer RAM 274, and an error-correction code unit (ECC) 275 within the interface unit (I/F) 272.

The interface unit (I/F) 271 transmits and receives a predetermined signal to and from the external device, and the interface unit (I/F) 272 transmits and receives a predetermined signal to and from the semiconductor memory device 250. The microprocessor unit (MPU) 273 converts a logical address to a physical address. The buffer RAM 274 temporarily stores data. The error-correction code unit (ECC) 275 generates an error-correction code.

A command signal line CMD, a clock signal line CLK, and the signal line DAT are connected to the memory card 260. The number of control signal lines, the bit width of the signal line DAT, and the circuit structure of the controller 276 may be modified as needed.

(Application 4)

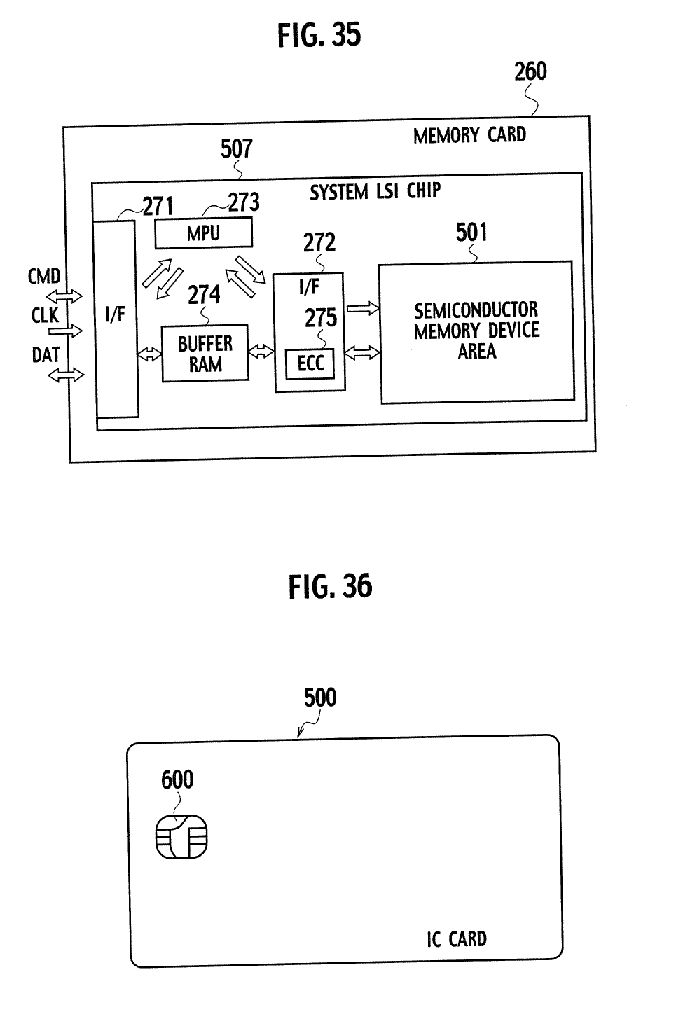

Yet another exemplary configuration of the memory card 260 implements a system LSI chip 507 that integrates the interface units (I/F) 271 and 272, the microprocessor unit (MPU) 273, the buffer RAM 274, the error-correction code unit (ECC) 275 included in the interface unit (I/F) 272, and a semiconductor memory device area 501, as shown in FIG. 35. Such system LSI chip 507 is mounted on the memory card 260.

(IC Card)

(Application 5)

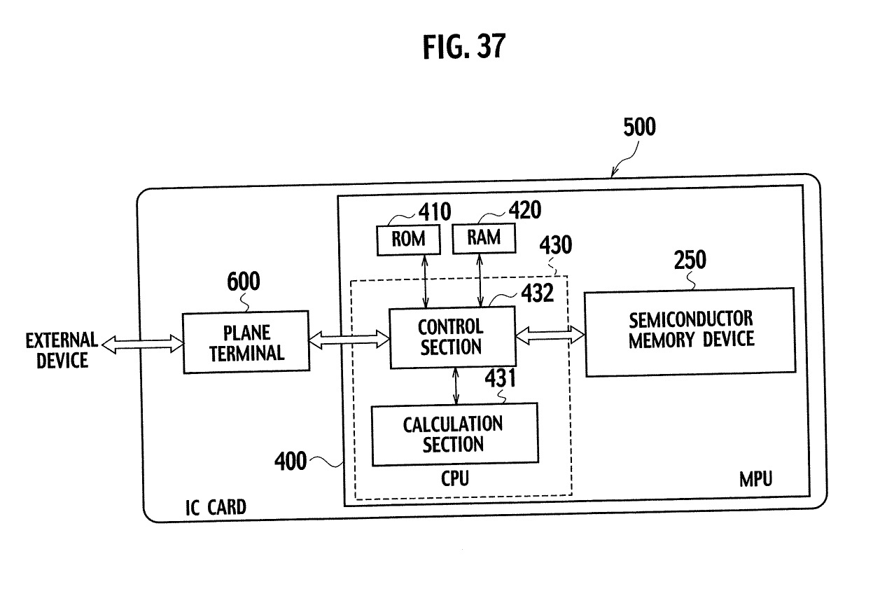

Yet another application of the nonvolatile semiconductor memory according to the first through the third embodiment of the present invention is constituted by an interface circuit (IC) card 500, which includes a MPU 400, which is constituted by the semiconductor memory device 250, ROM 410, RAM 420, and a CPU 430, and a plane terminal 600, as shown in FIGS. 36 and 37. The IC card 500 is connectable to an external device via the plane terminal 600. Furthermore, the plane terminal 600 is connected to the MPU 400 in the IC card 500. The CPU 430 includes a calculation section 431 and a control section 432. The control section 432 is connected to the semiconductor memory device 250, the ROM 410, and the RAM 420. It is preferable that the MPU 400 should be molded onto one surface of the IC card 500 and that the plane terminal 600 should be formed on the other surface of the IC card 500.

The nonvolatile semiconductor memory described in detail in the first through the third embodiment of the present invention may be applied to the semiconductor memory device 250 or the ROM 410 in FIG. 37. Furthermore, the page mode, the byte mode, and the pseudo EEROM mode are possible for the operation of the nonvolatile semiconductor memory.

(Application 6)

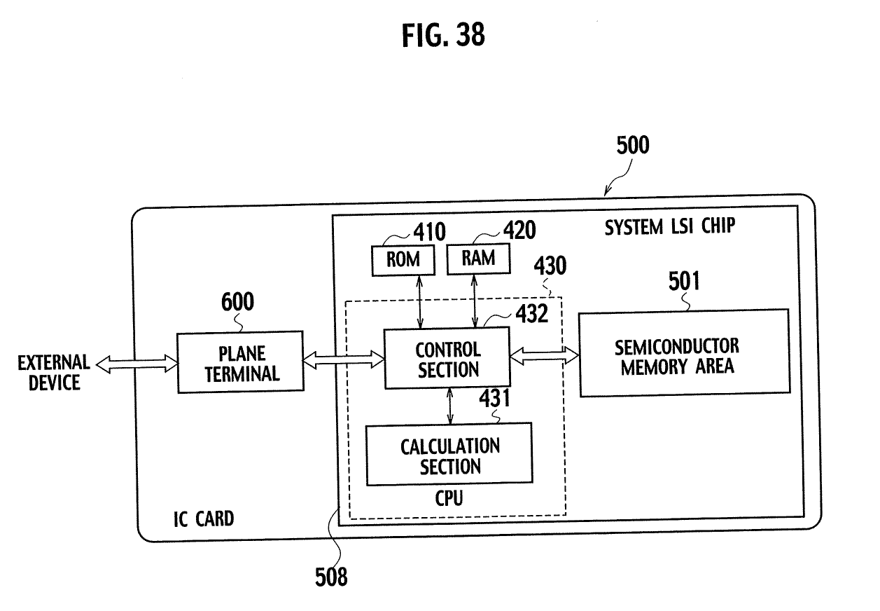

Yet another exemplary configuration of the IC card 500 includes a system LSI chip 508, which integrates the ROM 410, the ROM 420, the CPU 430, and the semiconductor memory device area 501, as shown in FIG. 38. Such a system LSI chip 508 is embedded in the memory card 500. The nonvolatile semiconductor memory described in detail in the first through the third embodiment of the present invention may be applied to the semiconductor memory device area 501 or the ROM 410 in FIG. 38. Furthermore, the page mode, the byte mode, and the pseudo EEROM mode are possible for the operation of the nonvolatile semiconductor memory.

### Other Embodiments

As described above, the present invention is described according to the first through the third embodiment; however, it should not be perceived that descriptions and drawings forming a part of this disclosure are not intended to limit the spirit and scope of the present invention. Various alternative embodiments, working examples, and operational techniques will become apparent from this disclosure for those skills in the art.

Various variations and modifications are naturally possible in the fabrication process for the memory cell transistor in the nonvolatile semiconductor memory according to the first through the third embodiment of the present invention.

Moreover, the memory cell transistor of the nonvolatile semiconductor memory according to the first through the third embodiment is not limited to binary logic memory. For example, multi-valued logic memory, more specifically three or more valued memory is also applicable. For example, four-valued nonvolatile semiconductor memory can have a memory capacity twice that of the two-valued nonvolatile semiconductor memory. In addition, the present invention is applicable to m or more valued nonvolatile semiconductor memory (m>3).

While NAND flash EEPROM has been described thus far, the configuration of the memory cell transistor in the nonvolatile semiconductor memory according to the first through the third embodiment and the fabrication method for the same hold true for memory according to other operating methods such as an AND type, a NOR type, a two-transistor/cell type, a three-transistor/cell type, or the like.

As such, the present invention naturally includes various embodiments not described herein. Accordingly, the technical scope of the present invention is determined only by specified features of the invention according to the following claims that can be regarded appropriate from the above-mentioned descriptions.

Various modifications will become possible for those skilled in the art after receiving the teachings of the present disclosure without departing from the scope thereof.

What is claimed is:

1. A nonvolatile semiconductor memory comprising:
a semiconductor layer disposed on an insulating layer;
a plurality of active regions extending along the column direction disposed in the semiconductor layer and isolated from each other by element isolating regions;
a plurality of word lines extending along the row direction perpendicular to the plurality of active regions; and
a plurality of memory cell transistors arranged in a matrix on the semiconductor layer, and each of the memory cell transistors which comprises, source/drain regions provided on the plurality of active regions; a floating gate polysilicon electrode layer sandwiched between the source/drain regions via a tunneling insulating film provided on the semiconductor layer; an inter-gate insulating film disposed on the floating gate polysilicon electrode layer; and a control gate metallic electrode layer disposed on the floating gate polysilicon electrode layer via the inter-gate insulating film.

2. The nonvolatile semiconductor memory of claim 1, wherein the source/drain regions have a same conductivity type with the semiconductor layer and the memory cell transistor operates in a depletion mode.

3. The nonvolatile semiconductor memory of claim 1, wherein the source/drain regions have an opposite conductivity type with the semiconductor layer and the memory cell transistor operates in an enhancement mode.

4. The nonvolatile semiconductor memory of claim 1, further comprising:
a buffer layer disposed between the inter-gate insulating film and the control gate metallic electrode layer.

5. The nonvolatile semiconductor memory of claim 1, wherein bottoms of the element isolation regions touch the surface of the insulating layer.

6. The nonvolatile semiconductor memory of claim 1, wherein bottoms of the element isolation regions are penetrating into the insulating layer.

7. The nonvolatile semiconductor memory of claim 1, wherein the control gate metallic electrode layer comprises a metallic silicide film.

8. The nonvolatile semiconductor memory of claim 7, wherein the metallic silicide film comprises one of the silicide materials of Cobalt, Nickel, Titanium, Tantalum, Platinum, Molybdenum, Tungsten, or Palladium.

9. A nonvolatile semiconductor memory comprising:
a semiconductor layer disposed on an insulating layer;
a plurality of active regions extending along the column direction disposed in the semiconductor layer and isolated from each other by element isolating regions;
a plurality of control gate lines extending along the row direction perpendicular to the plurality of active regions; and
a plurality of memory cell transistors arranged in a matrix on the semiconductor layer, and each of the memory cell transistors which comprises, source/drain regions provided on the plurality of active regions; a floating gate electrode layer sandwiched between the source/drain regions and disposed via a tunneling insulating film provided on the semiconductor layer;
an inter-gate insulating film disposed on sidewalls of the floating gate electrode layer and on the tunneling insulating film on the source/drain regions; and a control gate metallic electrode layer disposed facing the source/drain regions via the tunneling insulating film and the inter-gate insulating film and touching the sidewalls of the floating gate electrode layer via the inter-gate insulating film.

10. The nonvolatile semiconductor memory of claim 9, wherein the floating gate electrode layer comprises a polysilicon layer.

11. The nonvolatile semiconductor memory of claim 9, wherein the floating gate electrode layer comprises a metallic layer.

12. The nonvolatile semiconductor memory of claim 9, wherein the floating gate electrode layer comprises a metallic silicide layer.

13. The nonvolatile semiconductor memory of claim 12, wherein the metallic silicide film comprises one of the silicide materials of Cobalt, Nickel, Titanium, Tantalum, Platinum, Molybdenum, Tungsten, or Palladium.

14. The nonvolatile semiconductor memory of claim 9, wherein the source/drain regions have a same conductivity type with the semiconductor layer and the memory cell transistor operates in a depletion mode.

15. The nonvolatile semiconductor memory of claim 9, wherein the source/drain regions have an opposite conductivity type with the semiconductor layer and the memory cell transistor operates in an enhancement mode.

16. The nonvolatile semiconductor memory of claim 9, further comprising a buffer layer disposed between the inter-gate insulating film and the control gate metallic electrode layer.

17. The nonvolatile semiconductor memory of claim 9, wherein bottoms of the element isolation regions touch the surface of the insulating layer.

18. The nonvolatile semiconductor memory of claim 9, wherein bottoms of the element isolation regions are penetrating into the insulating layer.

19. The nonvolatile semiconductor memory of claim 9, wherein the control gate metallic electrode layer comprises a metallic silicide film constituted by one of the silicide materials of Cobalt, Nickel, Titanium, Tantalum, Platinum, Molybdenum, Tungsten, or Palladium.

20. A fabrication method for a nonvolatile semiconductor memory, comprising:
forming a tunneling insulating film on a semiconductor layer, which is formed on an insulating layer;
forming a floating gate polysilicon electrode layer on the tunneling insulating film;
etching and removing the floating gate polysilicon electrode layer, the tunneling insulating film, the semiconductor layer, and the insulating layer;
forming an element isolating region;
depositing an inter-gate insulating film on the floating gate polysilicon electrode layer and the element isolating region, and a nitride film on the inter-gate insulating film consecutively;
etching and removing the nitride film, the inter-gate insulating film, and the floating gate polysilicon electrode layer, exposing the tunneling insulating film;
forming source/drain regions in the semiconductor layer;
depositing an interlayer insulating film across the entire device surface;
planarizing the entire device surface, and exposing the nitride film and the interlayer insulating film;
removing the nitride film;
depositing a control gate metallic electrode layer across the entire device surface;
planarizing the entire device surface until the interlayer insulating film is exposed, and
filling in and forming the control gate metallic electrode layers through a metal damascene process.
